(19) United States
(12) Patent Application Publication
(10) Pub. No.: US 2011/0303971 A1
(43) Pub. Date: Dec. 15, 2011

(54) THREE-DIMENSIONAL SEMICONDUCTOR MEMORY DEVICE AND METHOD FOR MANUFACTURING THE SAME

(76) Inventors: Changwon Lee, Seongnam-si (KR); Kihyun Hwang, Seongnam-si (KR); Hanmei Choi, Seoul (KR); Sun Woo Lee, Incheon (KR); Junkyu Yang, Seoul (KR); Sunggil Kim, Suwon-si (KR); Jeonggil Lee, Goyang-si (KR); Seon-Ho Jo, Gimhae-si (KR)

(21) Appl. No.: 13/157,659

(22) Filed: Jun. 10, 2011

(30) Foreign Application Priority Data
Jun. 11, 2010 (KR) 10-2010-0055559

(51) Int. Cl. H01L 29/792

(52) U.S. Cl. 257/324; 257/E29.309

(57) ABSTRACT

A method for manufacturing a three-dimensional semiconductor memory includes forming a plurality of stacked structures disposed on a substrate to be spaced apart from each other, each of the stacked structures including a plurality of dielectric patterns and a plurality of polysilicon patterns alternately stacked, forming a metal layer to cover sidewalls of the stacked structures and a top surface of the substrate exposed between the stacked structures, and forming stacked gate electrodes on the substrate and a conductive line in the substrate by performing a silicidation process between the metal layer and each of the polysilicon patterns and the substrate.

### CROSS-REFERENCE TO RELATED APPLICATIONS

This U.S. non-provisional patent application claims priority under 35 U.S.C. §119 to Korean Patent Application No. 10-2010-0055559, filed on Jun. 11, 2010, the entirety of which is hereby incorporated by reference.

### BACKGROUND

1. Field

The inventive concept relates to semiconductor memory devices and methods for manufacturing the same. More particularly, the inventive concept is directed to methods for manufacturing a three-dimensional semiconductor memory device with improved integration density and electrical characteristics, and to a three-dimensional semiconductor memory device manufactured thereby.

2. Description of the Related Art

Higher integration of a semiconductor memory device has been required to meet users' needs for excellent functions and low cost. In case of a semiconductor memory device, increased integration density has been required because its integration density acts as an important cost determinant. In case of a conventional two-dimensional semiconductor memory device, its integration density is mainly determined by an area that a unit memory cell occupies. Therefore, the integration density of the conventional two-dimensional semiconductor memory device is rarely affected by the level of a fine patterns formation technique. However, since high-priced equipment is needed to achieve fine patterns, the integration density of a two-dimensional semiconductor memory device continues to increase but is still limited.

Three-dimensional semiconductor devices including three-dimensionally arranged memory cells have been proposed to overcome the above limitation. However, for the purpose of mass production of three-dimensional semiconductor devices, there is a need for processing techniques which are capable of reducing the manufacturing cost per bit and enhancing characteristics of reliable products.

### SUMMARY

Embodiments of the inventive concept provide a method for manufacturing a three-dimensional semiconductor memory device. The method may include forming a plurality of stacked structures disposed on a substrate to be spaced apart from each other, each of the stacked structures including a plurality of dielectric patterns and a plurality of polysilicon patterns alternately stacked, forming a metal layer to cover sidewalls of the stacked structures and a top surface of the substrate exposed between the stacked structures, and forming stacked gate electrodes on the substrate and a conductive line in the substrate by performing a silicidation process between the metal layer and each of the polysilicon patterns and the substrate.

Forming the stacked gate electrodes and the conductive line may include removing a portion of the metal layer that does not react with the polysilicon patterns and the substrate, the stacked gate electrodes and the conductive line including a metal silicide material formed in the silicidation process.

Performing the silicidation process may include reacting all of the polysilicon patterns with the metal layer.

Performing the silicidation process may include forming the stacked gate electrodes and the conductive line of nickel monosilicide having equal contents of silicon and nickel.

The method may further include, after forming the plurality of stacked structures, forming an impurity region on the substrate in an area exposed between the stacked structures, such that the conductive line includes the impurity region and a silicide material formed of at least a portion of the impurity region during the silicidation process.

Performing the silicidation process may include forming the silicide material of the impurity region to overlap a portion of a lower region of the stacked structure.

Forming the stacked structures may includes forming the stacked structure in one direction, and forming the polysilicon pattern to have a smaller horizontal width than that of the dielectric pattern, the horizontal width being measured in a plane perpendicular to an extension direction of the stacked structures.

Forming the metal layer may include filling a space between the dielectric patterns which are vertically adjacent to each other, thickness of the metal layer on a sidewall of the polysilicon pattern being equal to the horizontal width of the polysilicon pattern.

Forming the stacked structures may include forming a thin film structure having alternately stacked insulating layers and sacrificial layers on the substrate, forming semiconductor patterns penetrating the thin film structure and connected to the substrate, forming a trench penetrating the thin film structure between the semiconductor patterns to expose the substrate, removing the sacrificial layers exposed to the trench to form recessed regions between the insulating layers, and forming the polysilicon patterns in the recessed regions.

The method may further include, before forming the polysilicon patterns, forming a data storage pattern to be in contact with the semiconductor patterns in the respective recessed regions and a barrier metal pattern on the data storage pattern.

The method may further include, before forming the polysilicon patterns, forming a data storage layer in the recessed regions, forming a barrier metal layer on one sidewall of the thin film structure to fill the recessed region where the data storage layer is formed, and locally forming barrier metal patterns in the recessed regions, respectively, by anisotropically etching the barrier metal layer.

Embodiments of the inventive concept may provide another method for manufacturing a three-dimensional semiconductor memory device. The method may include forming a plurality of stacked structures spaced apart from each other on a silicon substrate, each of the stacked structures including a plurality of alternately stacked dielectric and polysilicon patterns, forming a metal layer in contact with the polysilicon patterns of the stacked structures and with the silicon substrate between the stacked structures, and performing a silicidation process, such that the polysilicon patterns and the silicon substrate interact with the metal layer to transform into stacked gate electrodes and a conductive line therebetween, respectively.

Embodiments of the inventive concept may also provide a three-dimensional semiconductor memory device. The three-dimensional semiconductor memory device may include a plurality of gate structures disposed on a substrate, the plurality of gate structures being spaced apart from each other and including a plurality of gate electrodes having metal silicide layers, semiconductor patterns traversing sidewalls of the gate structures and being connected to the substrate, and a conductive line disposed in the substrate between the gate structures, the conductive line including a metal silicide layer.

The metal silicide layers in the gate electrodes and in the conductive line may include nickel monosilicide having equal contents of silicon and nickel.

Each gate electrode may be the metal silicide layer.

The conducive line may include the metal silicide layer and an impurity region overlapping a portion of a lower region of the gate structure.

The structures may extend in one direction, a horizontal width of the metal silicide layer of the gate electrode being equal to a vertical thickness of the metal silicide layer of the conductive line in a plane which is vertical to an extension direction of the gate structures.

The three-dimensional semiconductor memory device may further include a barrier metal pattern locally formed between the semiconductor pattern and the gate electrode.

The barrier metal pattern may be in direct contact with the metal silicide layer of the gate electrode.

The three-dimensional semiconductor memory device may further include a data storage layer between the gate electrode and the semiconductor pattern.

The data storage layer may extend from one sidewall of the gate electrode to top and bottom surfaces of the gate electrode.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a circuit diagram of a three-dimensional semiconductor memory device according to embodiments of the inventive concept.

FIGS. 2 to 10 illustrate perspective views of stages in a method for manufacturing a three-dimensional semiconductor memory device according to an embodiment of the inventive concept.

FIGS. 11 to 16 illustrate different embodiments of portion “A” in FIG. 10.

FIGS. 17 to 19 illustrate cross-sectional views of stages in a method for manufacturing a three-dimensional semiconductor memory device according to another embodiment of the inventive concept.

FIGS. 20 to 24 illustrate cross-sectional views of stages in a method for manufacturing a three-dimensional semiconductor memory device according to another embodiment of the inventive concept.

FIGS. 25 and 26 illustrate perspective views of three-dimensional semiconductor memory devices according to modified embodiments of the inventive concept.

FIGS. 27 to 32 illustrate cross-sectional views of stages in a method for manufacturing a three-dimensional semiconductor memory device according to another embodiment of the inventive concept.

FIG. 33 illustrates a schematic block diagram of an embodiment of a memory system including a three-dimensional semiconductor memory device according to embodiments of the inventive concept.

FIG. 34 illustrates a schematic block diagram of an embodiment of a memory card including a three-dimensional semiconductor memory device according to embodiments of the inventive concept.

FIG. 35 illustrates a schematic block diagram of an embodiment of an information processing system fitted with a three-dimensional semiconductor memory device according to embodiments of the inventive concept.

### DETAILED DESCRIPTION

The inventive concept will now be described more fully hereinafter with reference to the accompanying drawings, in which embodiments of the inventive concepts are shown. This inventive concept may, however, be embodied in many different forms and should not be construed as limited to the embodiments set forth herein. Rather, these embodiments are provided so that this description will be thorough and complete, and will fully convey the invention to those skilled in the art. In the drawings, the size and relative sizes of layers and regions may be exaggerated for clarity. Like reference numerals refer to like elements throughout.

In the drawings, the thickness of layers and regions may be exaggerated for clarity. It will be understood that when an element is referred to as being “on,” “connected,” or “coupled” to another element, it can be directly on, connected, or coupled to the other element, or intervening elements may be present. In contrast, when an element is referred to as being “directly on,” “directly connected,” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first region/layer could be termed a second region/layer, and, similarly, a second region/layer could be termed a first region/layer without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising”, or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Embodiments of the inventive concept may be described with reference to cross-sectional illustrations, which are schematic illustrations of idealized embodiments of the inventive concept. As such, variations from the shapes of the illustrations, as a result, for example, of manufacturing techniques and/or tolerances, are to be expected. Thus, embodiments of the inventive concept should not be construed as limited to the particular shapes of regions illustrated herein, but are to include deviations in shapes that result from, e.g., manufacturing. For example, a region illustrated as a rectangle may have rounded or curved features. Thus, the regions illustrated in the figures are schematic in nature and are not intended to limit the scope of the inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

Spatially relatively terms, such as “beneath”, “below”, “above”, “upper”, “top”, “bottom” and the like, may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, when the device in the figures is turned over, elements described as below and/or beneath other elements or features would then be oriented (rotated 90° or at other orientations) and the spatially relative descriptors used herein interpreted accordingly. As used herein, “height” refers to a direction that is generally orthogonal to the faces of a substrate.

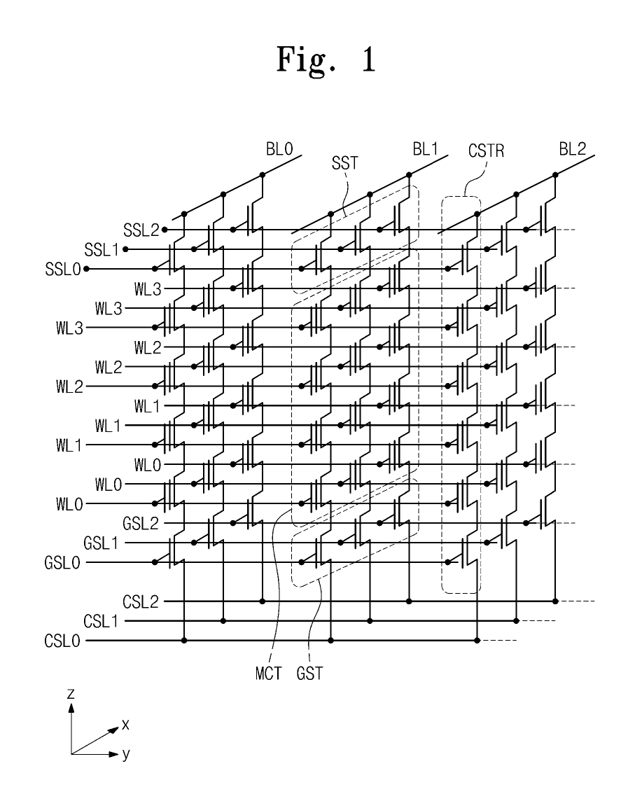

FIG. 1 is a circuit diagram of a three-dimensional semiconductor memory device according to embodiments of the inventive concept. As shown, the three-dimensional semiconductor memory device may include a plurality of common source lines CSL0, CSL1, and CSL2, a plurality of bitlines BL0, BL1, and BL2, and a plurality of cell strings CSTR disposed between one of the common source lines CSL0˜CSL2 and the bitlines BL0˜BL2.

The bitlines BL0˜BL2 are two-dimensionally arranged, and the plurality of cell strings CSTR are connected in parallel to the bitlines BL0˜BL2, respectively. The cell strings CSTR may be commonly connected to the common source lines CSL0˜CSL2. That is, a plurality of cell strings CSTR may be arranged between the plurality of bitlines BL0˜BL2 and one of the common source lines CSL0, CSL1 or CSL2. According to an embodiment, a plurality of common source lines CSL0˜CSL2 may be two-dimensionally arranged. In this case, a voltage may be equivalently applied to the common source lines CSL0˜CSL2, or the common source lines CSL0˜CLS2 may be separately controlled.

Each of the cell strings CSTR may include a ground selection transistor GST connected to the common source lines CSL0˜CSL2, a string selection transistor SST connected to the bitlines BL0˜BL2, and a plurality of memory cell transistors MCT disposed between the ground and string selection transistors GST and SST. The ground selection transistor GST, the string selection transistor SST, and the memory cell transistors MCT may be connected in series.

The common source lines CSL0˜CSL2 may be commonly connected to sources of the ground selection transistors GST. In addition, a plurality of ground selection lines GSL0˜GSL2, wordlines WL0˜WL3, and string selection lines SSL0˜SSL2 may be used as gate electrodes of the ground selection transistor GST, the memory cell transistors MCT, and the string selection transistor SST, respectively. Each of the memory cell transistors MCT includes a data storage.

Since one cell string CSTR includes a plurality of memory cell transistors MCT spaced different distances apart from the common source lines CSL0-CSL2, multi-layer wordlines WL0˜WL3 may be disposed between the common source lines CSL0˜CSL2 and the bitlines BL0˜BL2 in a z-axis direction that is perpendicular to an xy plane.

Gate electrodes of memory cell transistors MCT spaced a same distance from the common source lines CSL0-CSL2 may be connected in common to one of the word lines WL0-WL3, thereby having an equivalent electrical potential. Even though some gate electrodes of memory cell transistors MCT are spaced a same distance from the common source lines CSL0-CSL2, gate electrodes disposed in different rows and columns may be independently controlled.

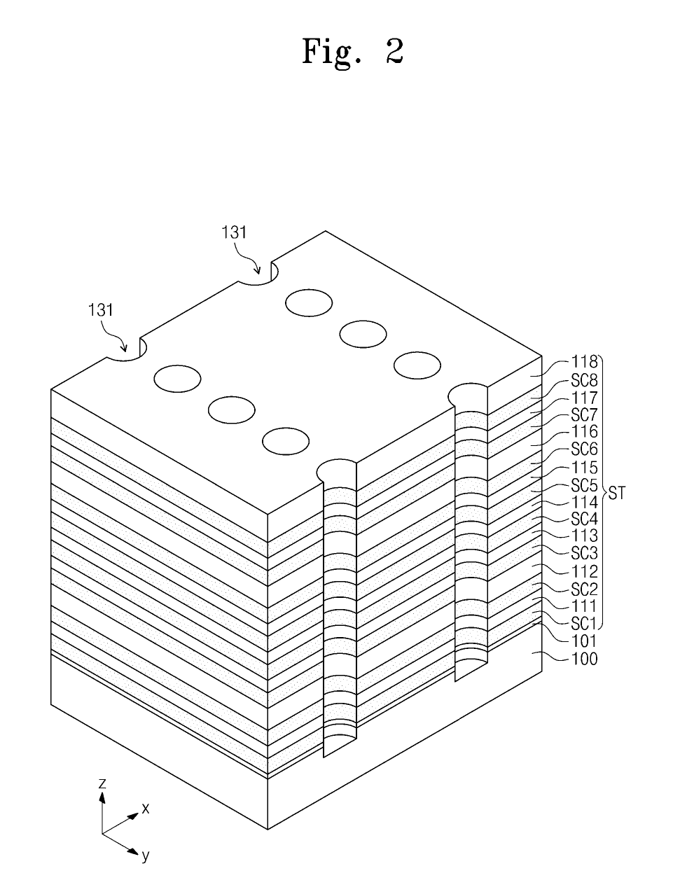

A method for manufacturing a three-dimensional semiconductor memory device according to an embodiment of the inventive concept will now be described below in detail with reference to FIGS. 2 to 10.

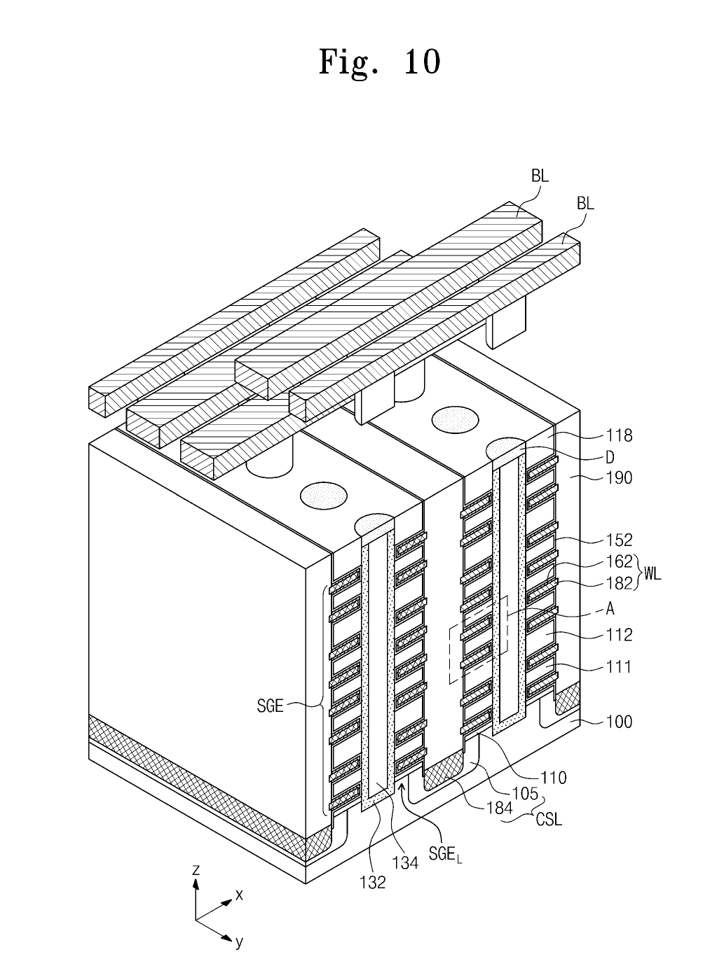

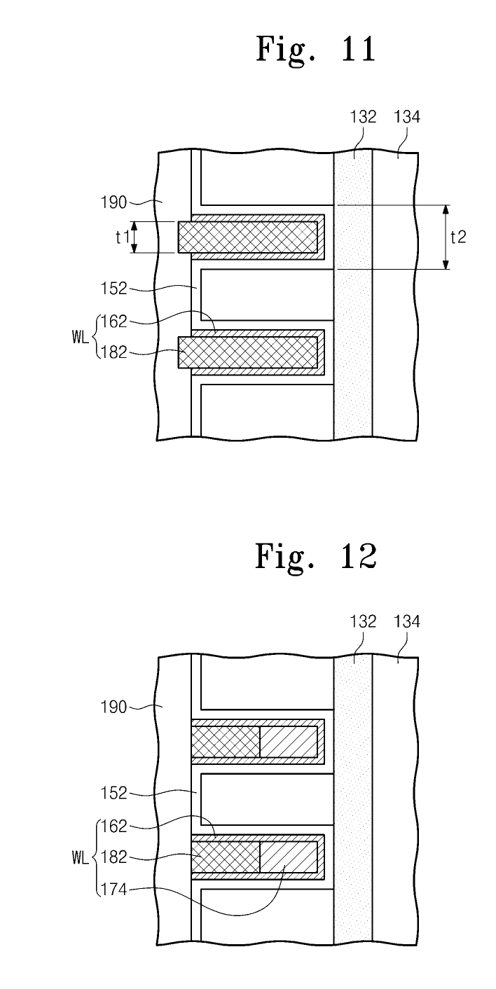

FIGS. 2 to 10 are perspective views illustrating a method for manufacturing a three-dimensional semiconductor memory device according to an embodiment of the inventive concept. FIGS. 11 to 16 illustrate a portion “A” shown in FIG. 10.

Referring to FIG. 2, a thin film structure ST is formed on a substrate 100. The thin film structure ST includes sacrificial layers SC1˜SC8 and insulating layers 111˜118 that are alternately stacked on the substrate 100.

The substrate 100 may be a material exhibiting semiconductor characteristics (e.g., silicon wafer, silicon, germanium, and/or silicon germanium), an insulating material (e.g., an oxide, a nitride, a glass, etc.), and/or a semiconductor covered with an insulating material (e.g., a silicon-on-insulator (SOI) substrate).

As shown, the insulating layers 111˜118 and the sacrificial layers SC1˜SC8 may be stacked alternately and repeatedly. The insulating layers 111˜118 and the sacrificial layers SC1˜SC8 may be formed of materials having an etch selectivity with respect to each other. For example, the insulating layers 111˜118 may be formed of at least one of silicon, silicon oxide, silicon carbide, and silicon nitride, and the sacrificial layers SC1˜SC8 may be formed of a material that is different than the material of the insulating layers 111˜118, e.g., a material different than silicon, silicon oxide, silicon carbide, or silicon nitride.

According to an embodiment, the sacrificial layers SC1˜SC8 may be formed to the same thickness. In another embodiment, a lowermost sacrificial layer SC1 and an uppermost sacrificial layer SC8 may be formed to be thicker than the sacrificial layers SC2˜SC7 disposed therebetween. In this case, the sacrificial layers SC2˜SC7 between the uppermost and lowermost sacrificial layers SC1 and SC8 may be formed to the same thickness.

According to an embodiment, an uppermost insulating layer 118 of the insulating layers 111˜118 may be formed to be thicker than underlying insulating layers 111˜117. The insulating layers 111˜117 below the uppermost insulating layer 118 may be formed to the same thickness. According to another embodiment, as shown in FIG. 2, predetermined insulating layers 112 and 116 of the insulating layers 111˜117 may be formed to be thicker than the other insulating layers 111, 113, 114, 115, and 117.

A buffer insulating layer 101 may be formed between the lowermost sacrificial layer SC1 and the substrate 100. The buffer insulating layer 101 may be formed to be thinner than the insulating layers 111˜118, and may be a silicon oxide layer formed by a thermal oxidation process.

Next, the thin film structure ST may be patterned to form openings 131, such that the substrate 100 is exposed. Specifically, forming openings 131 may include forming a mask pattern (not shown) on the thin film structure ST to define plane positions of the openings 131 and anisotropically etching the thin film structure ST by using the mask pattern as an etch mask.

The openings 131 may be formed to expose inner sidewalls of the sacrificial layers SC1˜SC8 and the insulating layers 111˜118. In addition, according to an embodiment, the openings 131 may be formed to expose a top surface of the substrate 100 through the buffer insulating layer 101. During the formation of the openings 131, the top surface of the substrate 100 exposed by the opening 131 may be recessed to a predetermined depth by overetching. A width of the opening 131, e.g., along the y-axis, may vary with respect to a distance from the substrate 100 by an anisotropic etch process.

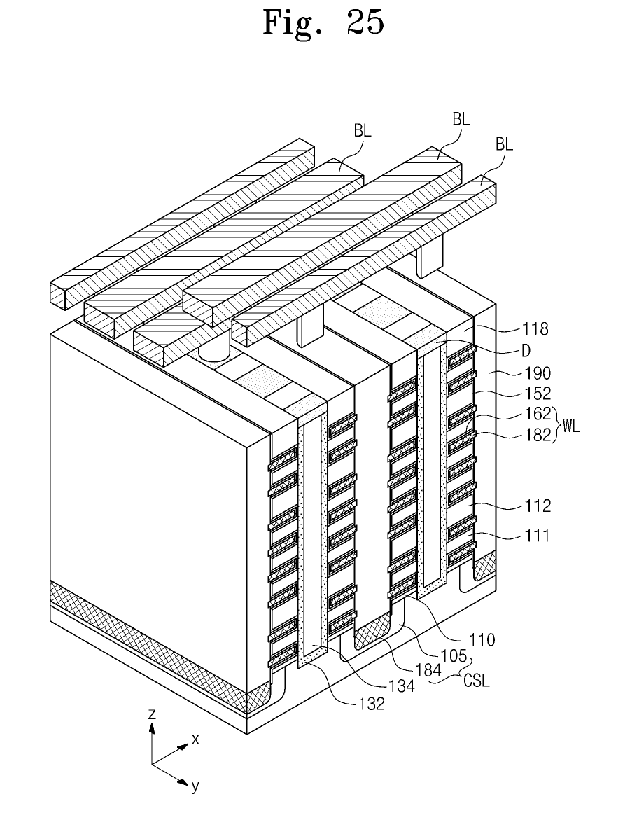

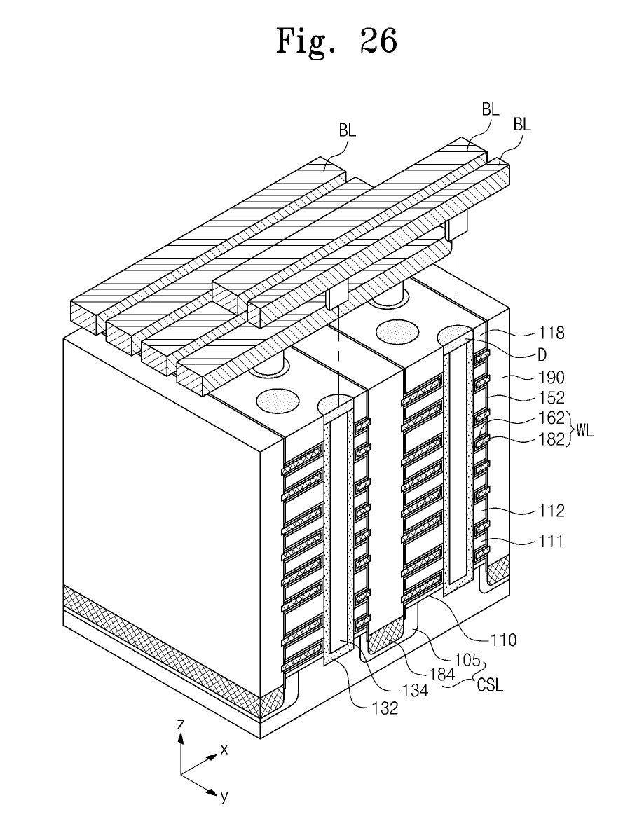

According to an embodiment, as shown in FIG. 2, each of the openings 131 may be formed to have the shape of a cylindrical hole or a rectangular parallelepiped hole, and may be two-dimensionally and regularly formed in the xy-plane. That is, the openings 131 may be disposed to be spaced apart from each other along the x-axis and the y-axis. According to another embodiment, as shown in FIG. 25, the openings may be line-shaped trenches extending along the z-axis and the y-axis, and may be parallel with each other and spaced apart from each other along the x-axis. According to another embodiment, as shown in FIG. 26, the openings may be disposed in a zigzag pattern along the y-axis. A distance between adjacent openings 131 along the y-axis may be equal to or less than a width of an opening along the y-axis. As such, when the openings are disposed in a zigzag pattern, a larger number of openings may be disposed in a predetermined area.

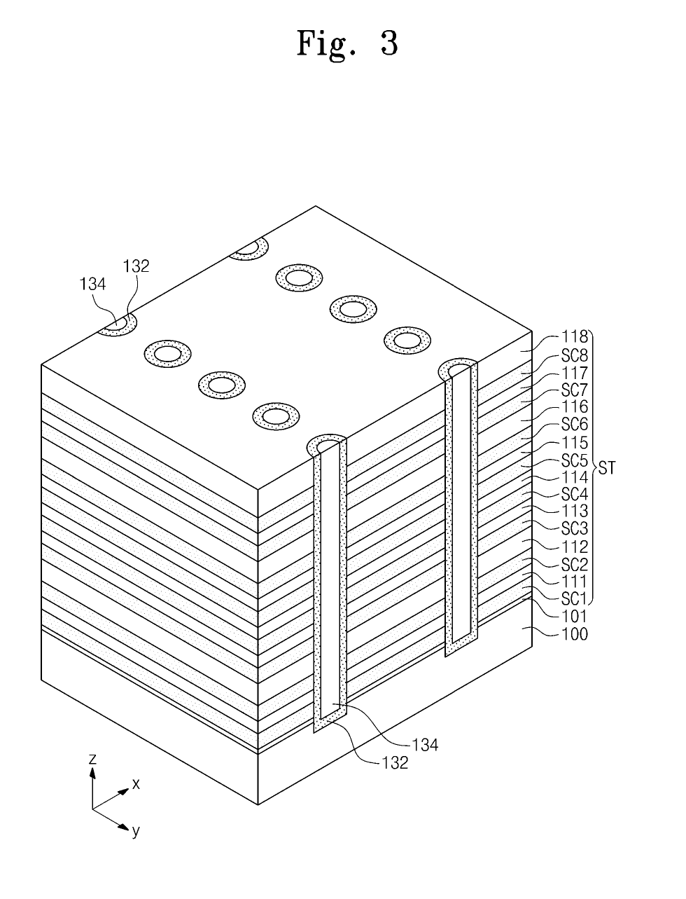

Referring to FIG. 3, a semiconductor pattern 132 may be formed in the respective openings 131. Specifically, the semiconductor pattern 132 may be formed in an opening to be in direct contact with the substrate 100, and may be substantially perpendicular to the substrate 100. For example, the semiconductor pattern 132 may be conformally formed on the inner sidewall of each opening 131. The semiconductor pattern 132 may include, for example, silicon (Si), germanium (Ge), or a combination thereof. The semiconductor pattern 132 may be a doped semiconductor or an undoped, i.e., intrinsic, semiconductor. The semiconductor pattern 132 may have at least one of a single-crystalline structure, an amorphous structure, and a polycrystalline structure.

The semiconductor pattern 132 may be formed in the respective openings 131 by a chemical vapor deposition (CVD) process or an atomic layer deposition (ALD) process. When the semiconductor pattern 132 is formed by a deposition process, a discontinuous boundary may be formed between the semiconductor pattern 132 and the substrate 100 due to a difference in crystalline structure between the semiconductor pattern 132 and the substrate 100. According to an embodiment, the semiconductor pattern 132 may be formed of single-crystalline silicon by depositing amorphous silicon or polysilicon and performing phase transition of the amorphous silicon or polysilicon by a heat treatment, e.g., laser annealing. According to another embodiment, the semiconductor pattern 132 may be formed in the respective openings 131 by an epitaxial process using the substrate 100 exposed by the openings 131 as a seed layer.

The semiconductor pattern 132 may be deposited to a thickness less than half a width of the opening 131. In this case, the semiconductor pattern 132 may only partially fill the opening 131 to define an empty region at a center of the opening 131. The thickness of the semiconductor pattern 132 may be less than a width of a depletion region to be formed in a semiconductor layer during an operation of a semiconductor memory device, or an average length of silicon grains constituting polycrystalline silicon. That is, the semiconductor pattern 132 may be formed in the respective openings 131 to exhibit a pipe shape, a hollow cylindrical shape, or a cup shape. A buried dielectric pattern 134 may fill the empty region in the center of the opening 131 defined by the semiconductor pattern 132. The buried dielectric pattern 134 may be formed of an insulating material having superior gap-fill characteristics. The buried dielectric pattern 134 may be formed of, e.g., high-density plasma oxide, spin-on-glass (SOG) and/or CVD oxide.

According to an embodiment, the semiconductor pattern 132 may be formed in the opening 131 by a deposition process to exhibit a cylindrical shape. In this case, the semiconductor pattern 132 may be planarized after being deposited. According to another embodiment, when the openings are formed in the shape of lines, semiconductor patterns 132 may be formed with dielectric patterns 111˜118 interposed therebetween in the opening (FIG. 25). Herein, forming the semiconductor patterns 132 may include sequentially forming a semiconductor layer and a buried dielectric layer in the openings 131 and patterning the semiconductor layer and the buried dielectric layer to form a semiconductor pattern 132 having a rectangular plane in the opening 131. The semiconductor pattern 132 may have a U-shape.

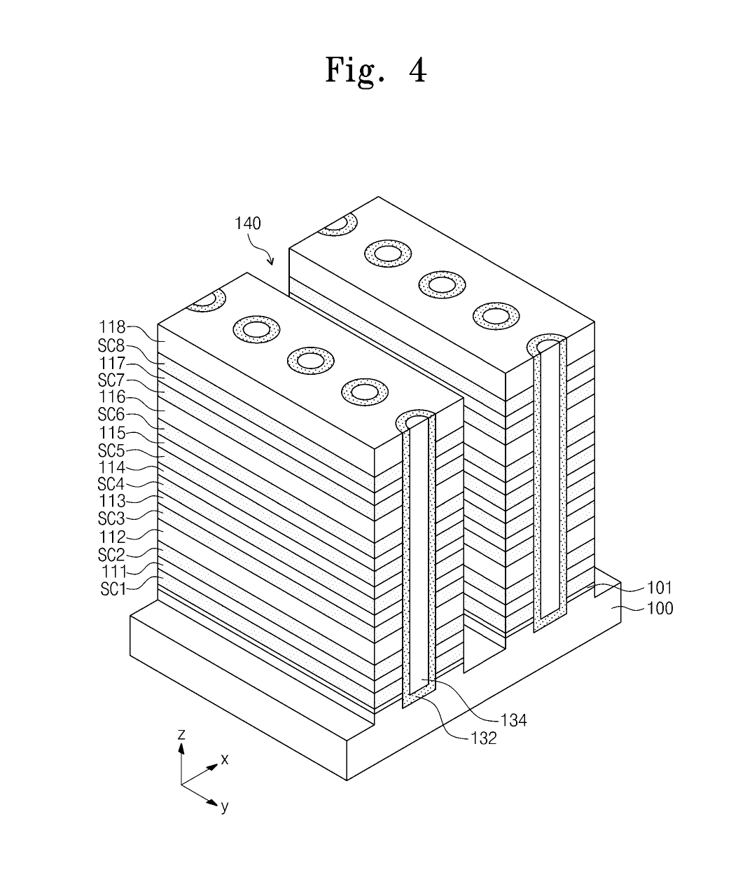

Referring to FIG. 4, after forming the semiconductor patterns 132, trenches 140 may be formed between adjacent semiconductor patterns 132 to expose the substrate 100. For example, forming the trenches 140 may include forming a mask pattern (not shown) on a thin film structure ST to define plane positions of the trenches 140 and anisotropically etching the thin film structure ST by using the mask pattern as an etch mask.

The trench 140 may be spaced apart from the semiconductor patterns 132, e.g., along the y-axis, to expose sidewalls of the sacrificial layers SC1˜SC8 and the insulating layers 111˜118. In terms of a horizontal shape, the trench 140 may be formed in the shape of a line or a rectangle. In terms of a vertical shape, the trench 140 may be formed to expose a top surface of the substrate 100. Width of the trench 140 may vary with a distance from the substrate 100 due to an isotropic etch process. During the formation of the trenches 140, the top surface of the substrate 100 exposed by the trench 140 may be recessed to a predetermined depth by overetching.

As the trenches 140 are formed, the thin film structure ST may have the shape of a line extending in a direction of y-axis. A plurality of semiconductor patterns 132 arranged in the direction of the y-axis may penetrate each one-line type thin film structure ST. As such, the trenches 140 provide the line-type thin film structure ST with an inner sidewall adjacent to the semiconductor pattern 132 and an outer sidewall exposed by the trench 140. That is, sacrificial patterns SC1˜SC8 and dielectric patterns 111˜118 may be alternatively and repeatedly stacked on the substrate 100.

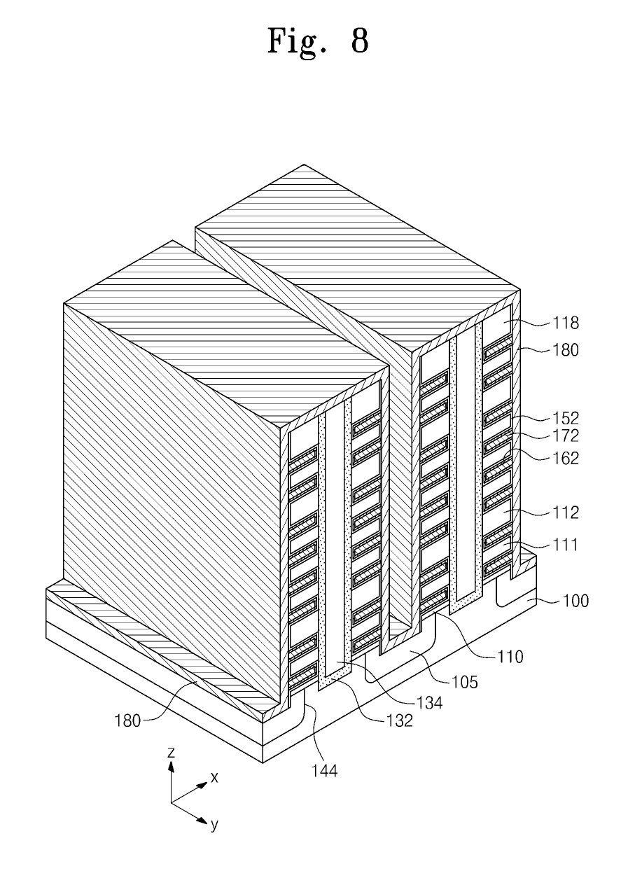

According to an embodiment, after forming the trenches 140, an impurity region 105 may be formed in the substrate 100 (see FIG. 8). The impurity region 105 may be formed by an ion implantation process using the thin film structure ST, where the trench 140 is formed, as an ion implantation mask. Due to impurity diffusion, the impurity region 105 may overlap a portion of a lower region of the thin film structure ST. The impurity region 105 may have a conductivity type opposite to that of the substrate 100.

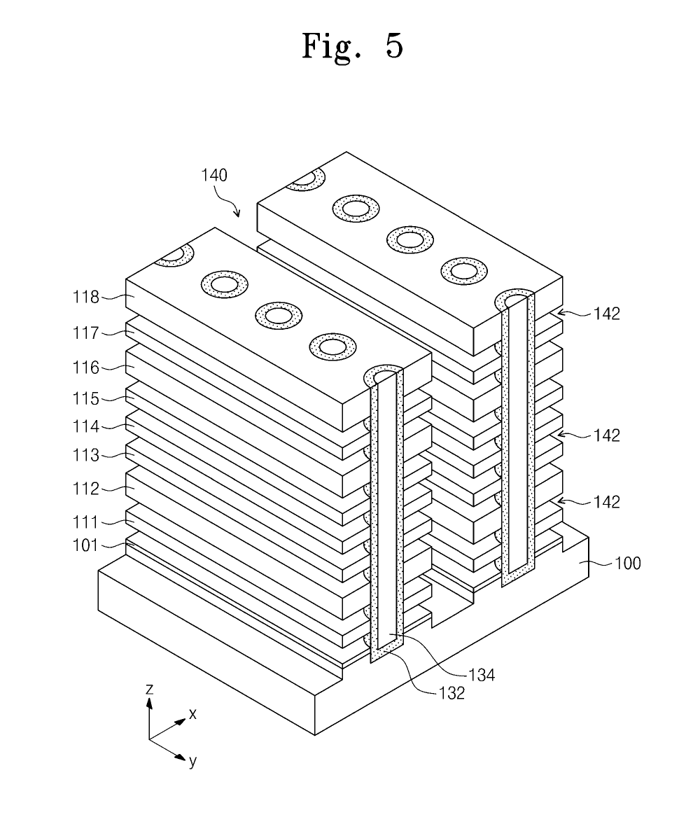

Referring to FIG. 5, the sacrificial patterns SC1˜SC8 exposed by the trenches 140 may be removed to form recessed regions 142 between the dielectric patterns 111˜118. The recessed region 142 may be formed by removing the sacrificial patterns SC1˜SC8 between the dielectric patterns 111˜118. That is, the recessed regions 142 may horizontally extend to a portion between the dielectric patterns 111˜118 from the trench 140. A recessed region 142 formed at a lowermost portion may be defined by a buffer insulating layer 101. A vertical thickness (a length in a direction of z-axis) of the recessed region 142 may be defined by the deposition thickness of the sacrificial layers SC1˜SC8 when the sacrificial layers SC1˜SC8 are deposited in FIG. 2.

For example, formation of the recessed regions 142 may include isotropically etching the sacrificial patterns SC1˜SC8 by using an etch recipe having an etch selectivity with respect to the dielectric patterns 111˜118. The sacrificial patterns SC1˜SC8 may be fully removed by an isotropic etch process. For example, if each of the sacrificial patterns SC1˜SC8 is formed of silicon nitride and each of the dielectric patterns 111˜118 is formed of silicon oxide, the etch step may be carried out using an etchant containing phosphoric acid.

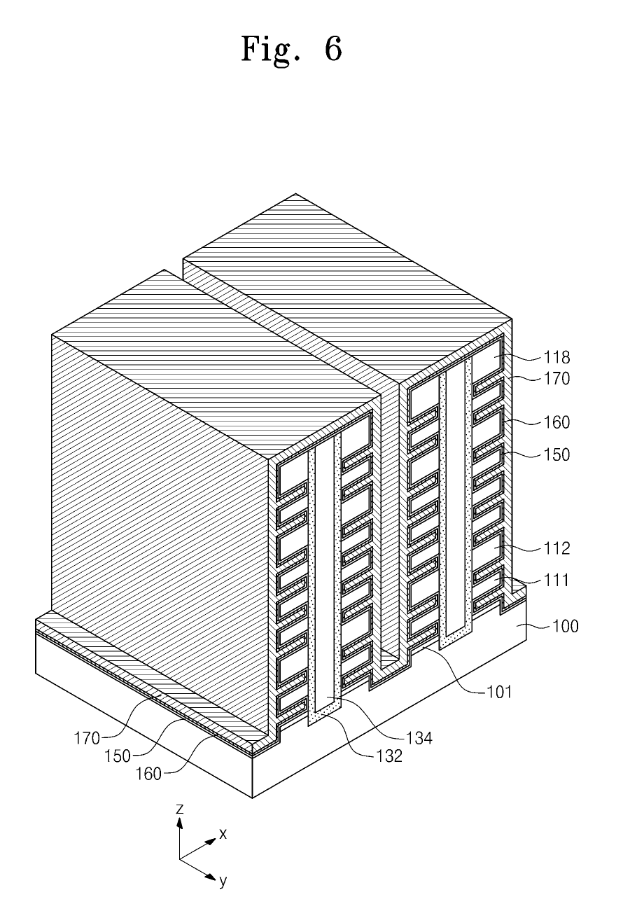

Referring to FIG. 6, a data storage layer 150 may be formed in the recessed regions 142. The data storage layer 150 may be formed to substantially and conformally cover the thin film structure ST where the recessed regions 142 are formed. The data storage layer 150 may be formed using a deposition technique (e.g., CVD or ALD) which is capable of providing superior step coverage. The data storage layer 150 may be formed to be thinner than half thickness of the recess regions 142. That is, the data storage layer 150 may be formed on sidewalls of the semiconductor patterns 132 exposed to the recessed region 142 and extend to bottom and top surfaces of the dielectric patterns 111˜118 defining the recessed region 142. In addition, the data storage layer 150 may be formed on exposed surface of the substrate 100 between the line-shaped thin film structure ST and a top surface of the uppermost dielectric pattern 118 and cover the sidewalls of the dielectric patterns 111˜118. Also, the data storage layer 150 may cover a top surface of the substrate 100 (or the buffer insulating layer 101) exposed by the recessed region 142 of a lowermost layer. That is, as shown in FIGS. 11 to 13, the data storage layer 150 may be conformally formed on a surface of the thin film structure ST where the recessed regions 142 are formed.

According to another embodiment, as shown in FIG. 14, a data storage pattern 154 may be locally formed between vertically adjacent dielectric patterns 111˜118 to be separated from other vertically adjacent data storage patterns 154. When the data storage patterns 154 are vertically separated from each other, charges trapped in the data storage pattern 154 may be prevented from spreading to another data storage pattern 154. Even when the data storage pattern 154 is locally formed between vertically adjacent dielectric patterns 111˜118, a lowermost data storage pattern 154 may be in direct contact with a top surface of the buffer insulating layer 101 (or the substrate 100).

According to an embodiment, the data storage layer 150 may be a charge storage layer. For example, the charge storage layer may include either one of a charge trapping dielectric layer and an insulating layer including a floating gate electrode or conductive nanodots. In the case where the data storage layer 150 is a charge storage layer, data stored in the data storage layer 150 may be altered using Fowler-Nordheim tunneling (FN tunneling) arising from a difference between voltages of the semiconductor pattern 132 and gate electrodes (WL in FIG. 10). The data storage layer 150 may be a thin film (e.g., a thin film for a phase change memory or a thin film for a variable resistance memory) which is capable of storing data based on a different operation principle.

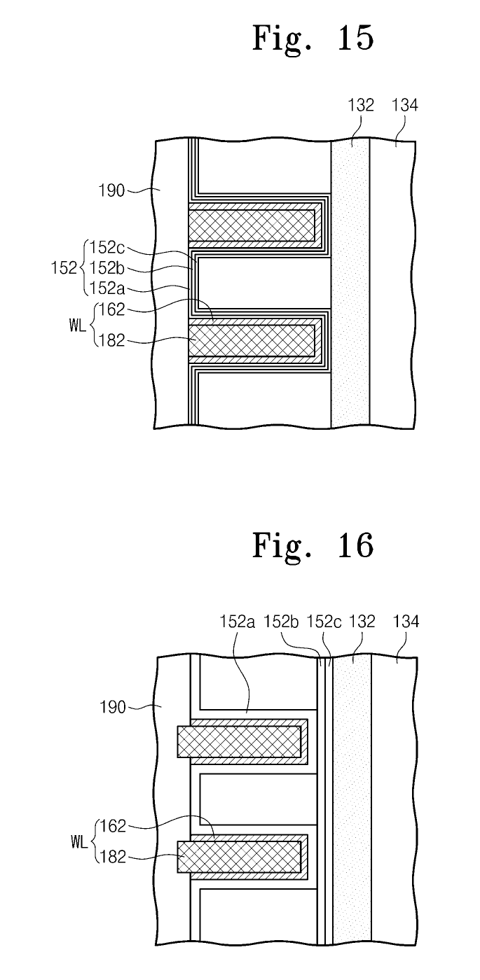

According to an embodiment, as shown in FIG. 15, the data storage layer 150 may include a blocking dielectric layer 152a, a charge trapping layer 152b, and a tunneling dielectric layer 152c which are sequentially stacked in the order named. The blocking dielectric layer 152a may include at least one of silicon oxide, silicon nitride, silicon oxynitride, and a high-k dielectric material. The blocking dielectric layer 152a may include a plurality of layers. The high-k dielectric material refers to a material with a higher dielectric constant (k) than silicon oxide and may include, e.g., tantalum oxide, titanium oxide, hafnium oxide, zirconium oxide, aluminum oxide, yttrium oxide, niobium oxide, cesium oxide, indium oxide, iridium oxide, BST, and/or PZT. The tunneling dielectric layer 152c may be formed to have a lower dielectric constant than the blocking dielectric layer 152a. The charge trapping layer 152b may be an insulating thin film (e.g., a silicon nitride layer) including abundant charge trap sites or an insulating thin film including conductive grains. According to an embodiment, the tunneling dielectric layer 152c may be a silicon oxide layer, the charge trapping layer 152b may be a silicon nitride layer, and the blocking dielectric layer 152a may be a dielectric layer including aluminum oxide.

According to another embodiment, the blocking dielectric layer 152a may include a first blocking dielectric layer and a second blocking dielectric layer. The first and second blocking dielectric layers may be formed of different materials. One of the first and second blocking dielectric layers may be formed of a material having a band gap that is smaller than that of a tunneling dielectric layer and greater than that of a charge trapping layer. For example, the first blocking dielectric layer may be formed of a high-k dielectric material, e.g., aluminum oxide or hafnium oxide, and the second blocking dielectric layer may be formed of a material having a lower dielectric constant than the first blocking dielectric layer. According to another embodiment, the second blocking dielectric layer is formed of a high-k dielectric layer, and the first blocking dielectric layer may be formed of a material having a lower dielectric constant than the second blocking dielectric layer.

According to yet another embodiment, in the data storage layer 150 including the blocking dielectric layer 152a, the charge trapping layer 152b, and the tunneling dielectric layer 152c, which are stacked in the order named, the tunneling dielectric layer 152c and the charge trapping layer 152b are formed across an inner wall of a thin film structure ST adjacent to the semiconductor pattern 132, as shown in FIG. 16. That is, the tunneling dielectric layer 152c and the charge trapping layer 152b may be formed on an inner wall of an opening before forming the semiconductor pattern 132. The blocking dielectric layer 152a may be conformally formed in the recessed region 142 after forming the recessed regions 142. Thus, the blocking dielectric layer 152a may be in direct contact with top and bottom surfaces of a dielectric pattern. Alternatively, after forming the recessed regions 142, the charge trapping layer 152b and the blocking dielectric layer 152a may be conformally formed in the recessed region 142.

A general description of the gate electrodes WL, i.e., wordlines WL in FIG. 1, and common source lines CSL according to example embodiments will be described hereinafter. A detailed description of a method of forming the gate electrodes WL and common source lines CSL will be provided with reference to FIGS. 6-10 later.

The gate electrodes WL are formed in the recessed regions 142 where the charge storage layer 150 is formed, respectively. When the gate electrodes WL are formed, a common source conductive line CSL is formed in the substrate 100.

As the gate electrode WL is formed in the recessed region 142 where the data storage layer 150 is conformally formed, a vertical thickness (t1 in FIG. 11) of the gate electrode WL may be reduced to be less than a vertical thickness (t2 in FIG. 11) of the recessed region 142. Such a thickness reduction of a gate electrode may potentially increase resistance of a conventional gate electrode. While a gate electrode may be formed of a low-resistivity metal (e.g., tungsten) to decrease resistivity thereof, such a gate electrode may exhibit a rapid increase of resistance when the low-resistivity metal is below a predetermined thickness, e.g., when a gate electrode is formed of tungsten having a thickness lower than about 500 angstroms.

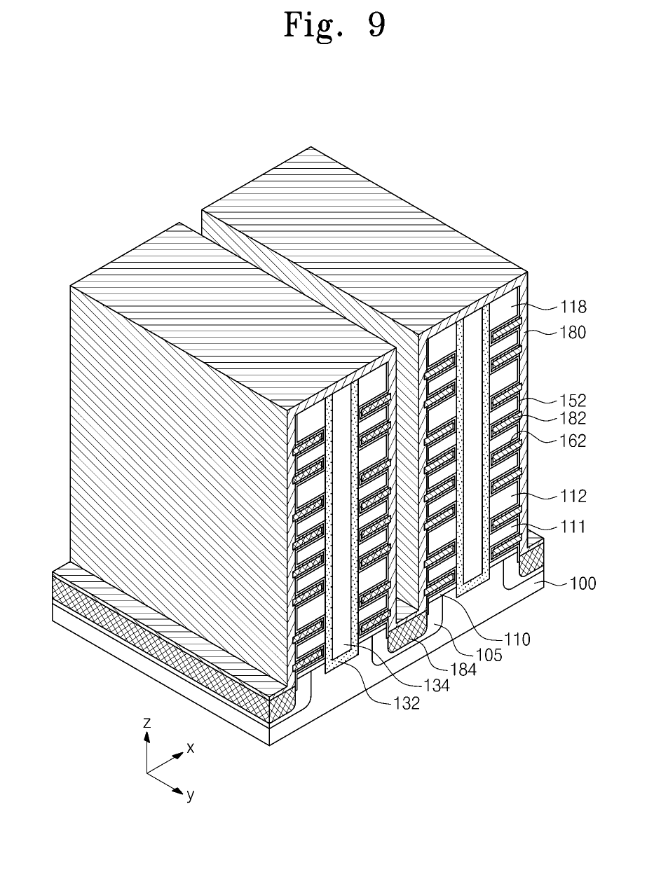

Therefore, according to example embodiments, the gate electrode WL may be formed of a metal silicide having lower resistance than a low-resistivity metal, e.g., lower resistance than a tungsten layer, and a lower thickness than the predetermined thickness, e.g., the gate electrode WL may includes a gate silicide layer 182 having a vertical thickness ranging from about 100 to about 500 angstroms (FIG. 9). Since the gate electrode WL includes a metal silicide, resistance of the gate electrode WL may be reduced and operation characteristics of a three-dimensional semiconductor memory device may be improved. As such, integration density and electrical characteristics of the three-dimensional semiconductor memory device may be improved.

The common source line CSL may include the impurity region 105 formed in the substrate 100. Conventionally, it may be difficult to maintain resistance, and resistance of a common source line including an impurity region may be high. Thus, according to example embodiments, the common source line CSL may include the impurity region 105 and a common source silicide layer 184 (FIG. 8). Resistance of the common source line CSL including the metal silicide layer 184 may be reduced to be less than that of a conventional common source line CSL, i.e., a common source line including an impurity region without a silicide layer. Furthermore, as the common source silicide layer 184 of the common source line CSL may be formed simultaneously with the gate silicide layer 182 of the gate electrode WL, manufacturing of the three-dimensional semiconductor memory device may be simplified.

A method for forming the gate electrodes WL and the common source lines CSL will now be described in detail with reference to FIGS. 6 to 10. According to example embodiments, formation of the gate electrodes WL and common source lines CSL may include forming a polysilicon layer 170 in the trench 140 and the recessed region 142, i.e., where the data storage layer 150 is formed, followed by removing the polysilicon layer 170 in the trench 140 to form polysilicon patterns 172 vertically separated from each other, and siliciding the polysilicon patterns 172 and the substrate 100 exposed to the trench 140 to form the gate electrodes WL and the common source lines CSL. As the metal silicide layer 182 is formed on the data storage layer 150, a barrier metal layer 160 may be formed before forming the polysilicon layer 170 to fill the recessed region 142.

In detail, referring to FIG. 6, the barrier metal layer 160 may be conformally formed along a surface of the data storage layer 150. The barrier metal layer 160 may prevent a metal material from penetrating the data storage layer 150 and is formed of a conductive material having low resistivity to reduce resistance of a gate electrode. The barrier metal layer 160 may be formed of, for example, metal, e.g., titanium, tantalum, and/or tungsten, and/or a conductive metal nitride, e.g., titanium nitride, tantalum nitride, and/or tungsten nitride.

For example, the barrier metal layer 160 may be thinly and uniformly formed on a surface of the data storage layer 150 formed in the recessed region 142. That is, the barrier metal layer 160 is formed on a sidewall of the semiconductor pattern 132 and top and bottom surfaces of the dielectric patterns 111˜118 to reduce a space of the recess region between the dielectric patterns 111˜118. The barrier metal layer 160 may be formed by chemical vapor deposition (CVD), atomic layer deposition (ALD), or sputtering deposition. The barrier metal layer 160 may be formed to a small thickness ranging from about 10 to about 100 angstroms. The barrier metal layer 160 may be formed of titanium nitride. The titanium nitride may be generated using titanium tetrachloride (TiCl₄) gas and ammonia (NH₃) gas as reaction gases.

Next, the polysilicon layer 170 may be formed in the recessed regions 142 where the barrier metal layer 160 is formed. The polysilicon layer 170 may be formed of polysilicon doped with N-type or P-type impurity (boron or phosphorus) or an amorphous polysilicon. The polysilicon 170 may be formed using a deposition technique (e.g., CVD, ALD, or sputtering) which is capable of providing superior step coverage. Accordingly, the polysilicon layer 170 may be conformally formed in the trench 140 while filling the recessed regions 142.

In detail, the polysilicon layer 170 may be deposited to a thickness which is equal to or higher than half vertical thickness of the recessed region 142. In the case where a plane (or horizontal) width of a trench is greater than a vertical thickness of the recessed region 142, the polysilicon layer 170 may only partially fill the trench 140, thereby defining an empty region at a center of the trench 140. In this case, the empty region may have an open top.

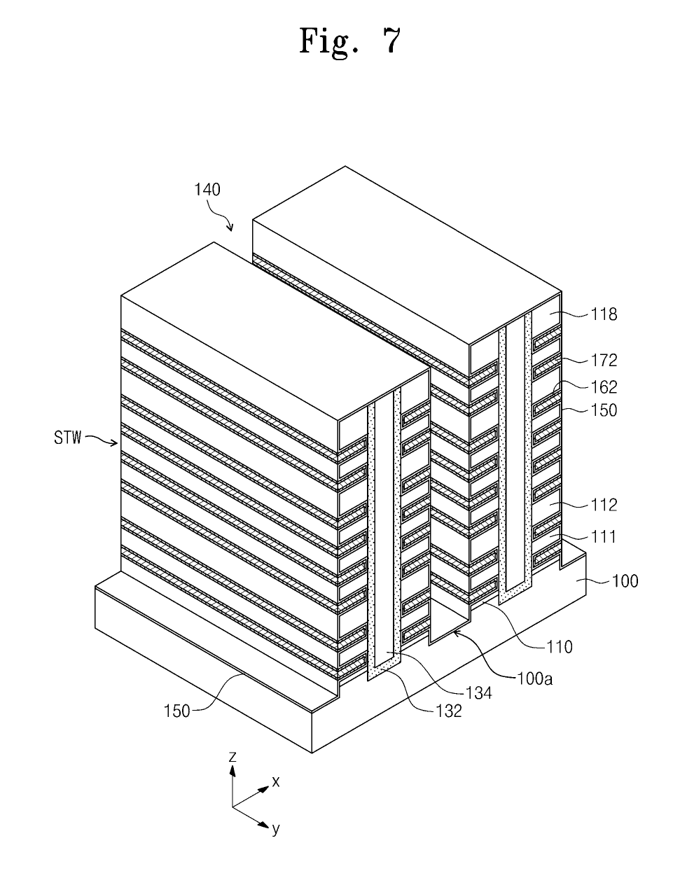

Referring to FIG. 7, the barrier metal 160 and the polysilicon layer 170 filling the trench 140 may be removed to form a barrier metal pattern 162 and a polysilicon pattern 172 in the recessed regions 142, respectively. The barrier metal pattern 162 and the polysilicon patterns 172 may constitute a stacked structure. Between adjacent trenches 140, the stacked structure may have a shape of line through which the semiconductor patterns 132 are formed.

In detail, forming the polysilicon pattern 172 includes isotropically etching the polysilicon layer 170 filling the trench 140. Due to the isotropic etch process, the polysilicon layer 170 may be substantially uniformly formed vertically and horizontally. The isotropic etch process for the polysilicon layer 170 may be performed until adjacent polysilicon patterns 172 may be separated. At this point, the barrier metal layer 160 may be used as an etch-stop layer. That is, sidewalls of the polysilicon layer 170 and the barrier metal layer 160 on the top surface of the substrate 100 may be exposed by the etch process for the polysilicon layer 170. In addition, the polysilicon layer 170 formed on an uppermost dielectric pattern constituting a thin film structure ST may be also etched by the isotropic etch process.

According to an embodiment, because an etch gas or etchant may be uniformly supplied to an empty region defined by polysilicon layer 170, while isotropically etching the polysilicon layer 170, the polysilicon layer 170 formed at the sidewall and a bottom portion of the empty region may be substantially etched at the same time. Thus, horizontal width (length in a direction of x-axis) of the polysilicon pattern 172 may be uniform from the lower portion to the upper portion of the thin film structure ST.

The isotropic etch process may be a wet etch process using an etch solution. Alternatively, the isotropic etch process may be a dry etch process using an etch gas. In the case where the isotropic etch process is a dry etch process, etch gases of a radical state and/or an ion state may be supplied into an empty region by diffusion of impurities. Thus, the etch gases may perform the isotropic etch process. When the polysilicon layer 170 is dry etched, an upper insulating layer constituting a thin film structure or a hard mask pattern (not shown) additionally formed thereon may be used as a hard mask.

The barrier metal patterns 162 may be formed at the recessed regions 142 by removing the barrier metal layer 160 exposed to the trench 140. The barrier metal layer 160 exposed to the trench 140 may be etched by an isotropic etch process. As the isotropic etch process is performed, the barrier metal layer 160 may be substantially uniformly etched vertically and horizontally. The isotropic etch process for the barrier metal layer 160 may be performed until the barrier metal patterns 162 are separated from each other and the data storage layer 150 may be used as an etch-stop layer. That is, sidewalls of the insulating layers 111˜118 and the data storage layer 160 on the top surface of the substrate 100 may be exposed by the etch process for the barrier metal layer 160.

The isotropic etch process may be a wet etch process using an etch solution. Alternatively, the isotropic etch process may be a dry etch process using an etch gas. For example, etching a barrier metal layer may be carried out by chemical mechanical etching, e.g., a reaction ion etching (RIE), a wet etching using an etchant, a chemical pyrolysis etching (e.g., gas-phase etch (GPE)), or a combination thereof.

For example, when the barrier metal layer 160 is formed of titanium nitride, the barrier metal layer 160 exposed to the trench 140 may be removed using a gas-phase etchant generated from a source gas containing a fluorine group (e.g., CF₄ and C₂F₆) and a chlorine group (e.g., Cl₂). The use of gas-phase etchant allows the barrier metal layer 160 exposed to the trench 140 to be uniformly removed.

When a barrier metal layer formed of titanium nitride is removed, a mixture of ammonium hydroxide (NH₄OH), hydrogen peroxide (H₂O₂), and deionized water (DI water) and a mixture of sulfuric acid (H₂SO₄) and hydrogen peroxide (H₂O₂) may be used. The mixture of ammonium hydroxide (NH₄OH), hydrogen peroxide (H₂O₂), and deionized water (DI water) is generally referred to as standard clean 1 (SC1).

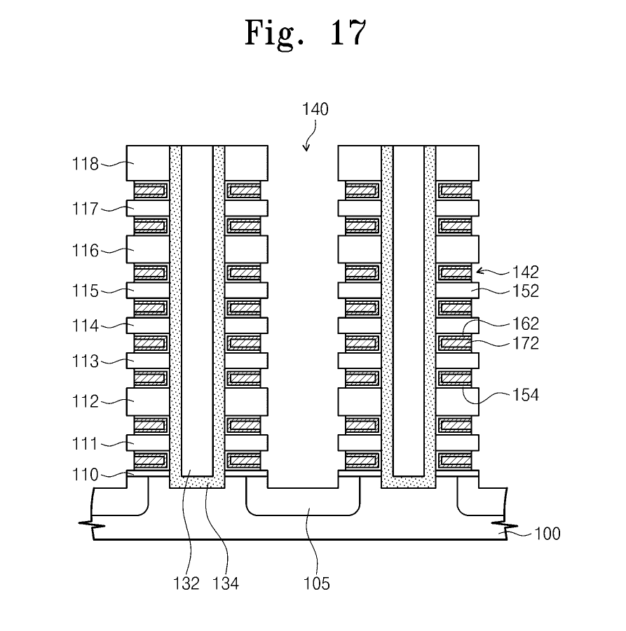

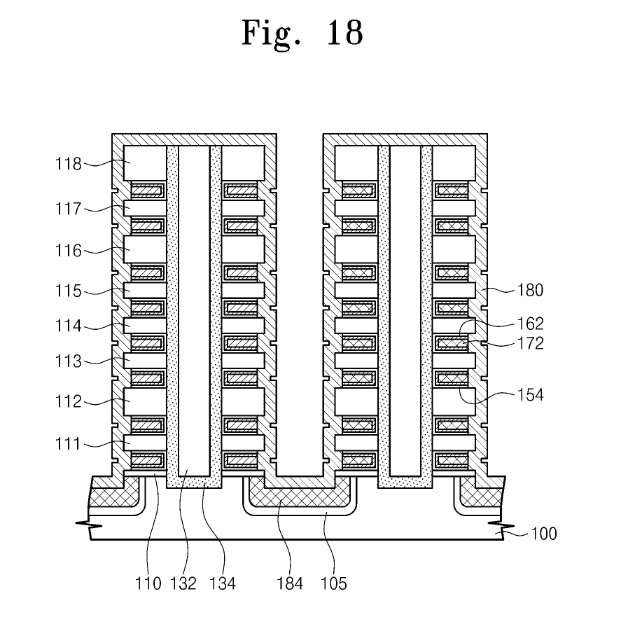

According to another embodiment, the isotropic etch process for the polysilicon layer 170 and the barrier metal layer 160 may determine horizontal widths (lengths in a direction of x-axis) of the polysilicon pattern 172 and the barrier metal pattern 162. For example, as shown in FIG. 17, the polysilicon pattern 172 and the barrier metal pattern 162 may be formed to fill a portion of the recessed region 142. Thus, the horizontal width of the polysilicon pattern 172 may be less than that of the respective dielectric patterns 111˜118.

Referring to FIG. 8, after forming the polysilicon pattern 172 and the barrier metal pattern 162, the impurity region 105 may be formed in the substrate 100 below the trench 140. The impurity region 105 may be formed using an uppermost dielectric pattern of the thin film trench as an ion implantation mask. Thus, the impurity region 105 may have a shape of a line extending in one direction like a horizontal shape of the trench 140. The impurity region 105 may partially overlap a lower portion of the thin film structure ST due to diffusion of impurities, i.e., a lower portion SGE_{L} of stacked gate electrodes SGE (FIG. 10). During formation of the impurity region 105, the data storage layer 150 disposed on the bottom surface of the trench 140 may be used as an ion implantation buffer layer. According to another embodiment, as described with reference to FIG. 4, the impurity region 105 may be formed in the substrate 100 below the trench 140 after forming the trench 140.

After forming the polysilicon pattern 172 at the recessed regions 142, the data storage layer 150 formed on the substrate 100 is selectively etched to expose the substrate 100. During the isotropic etch process for forming the polysilicon pattern 172 and the barrier metal pattern 162, the data storage layer 150 formed on the substrate 100 may be removed within the trench 140 by overetching. In addition, the data storage layer 150 formed on the substrate 100 may be selectively removed by an anisotropic etch process. As the data storage layer 150 is removed by the anisotropic etch process, the impurity region 105 formed in the substrate 100 may be exposed to the trench 140. Also the data storage layer 150 formed on the uppermost dielectric pattern 118 of the thin film structure may be removed by the anisotropic etch. As the data storage layer 150 is anisotropically etched, a data storage layer 152 may remain on the sidewalls of the dielectric patterns 111˜118 of the thin film structure, as shown in FIG. 8. In addition, the data storage layer 152 may remain on the sidewall of the recessed region 144 formed at the substrate 100.

According to a modified embodiment of the inventive concept, after forming the polysilicon pattern 172 and the barrier metal pattern 162, selectively removing the data storage layer 150 formed on the top surface of the substrate 100 and the sidewalls of the dielectric patterns 111˜118 may be carried out. Specifically, selectively removing the data storage layer 150 may include using an etch gas or an etch solution having an etch selectivity with respect to a gate conductive layer. For example, when the data storage layer 150 formed on the sidewalls of the dielectric patterns 111˜118 is removed by an isotropic etch process, the isotropic etch process may use an etch solution such as HF, O₃/HF, phosphoric acid, sulfuric acid, and/or LAL (mixture of NH₄F and HF). In addition, a fluoride-based etch solution and a phosphoric or sulfuric acid solution may be used to remove portions of the data storage layer 150.

An etch process of the data storage layer 150 may be carried out until the data storage patterns 154 are vertically separated from each other. During the etch process, the dielectric patterns 111˜118 and the substrate 100 may be used as etch-stop layers. That is, the sidewalls of the dielectric patterns 111˜118 and the top surface of the substrate 100 may be exposed by the etch process of the data storage layer 150. Thus, as shown in FIGS. 14 and 17, a data storage pattern 154 may be formed at the respective recessed regions 142. As a result, the data storage patterns 154 may be vertically separated from each other.

Continuing to refer to FIG. 8, a metal layer may be formed to cover the impurity region 105 and the polysilicon patterns 172 which are exposed to the trench 140, i.e., sidewalls STW of the thin film structures ST and a top surface 100a of the substrate 100 exposed between adjacent thin film structures ST. The metal layer 180 may be formed of a refractory metal, e.g., cobalt (Co), titanium (Ti), nickel (Ni), tungsten (W), and/or molybdenum (Mo), and/or an alloy including, e.g., platinum (Pt), rhenium (Re), boron (B), aluminum (Al), and/or germanium (Ge). In this way, a work function of the gate electrode WL may be controlled by adding an alloy material to a refractory metal. The metal layer 180 may be formed by a CVD, ALD, or a sputtering deposition process, such that the metal layer 180 may contact the polysilicon patterns 172 and the impurity region 105 which are exposed to the trench 140. Thickness of the metal layer 180 may be determined in consideration of the resistance of the gate electrode WL (FIG. 10) and the resistance of the common source line CSL (FIG. 10). For example, the metal layer 180 may be deposited to have a substantially same horizontal width as that of the polysilicon pattern 172.

According to another embodiment, as shown in FIG. 18, when the polysilicon patterns 172 are recessed into the recessed region 142, a metal layer 180 may be formed in the trench 140 while filling a portion of the recessed region 142. Thus, the metal layer 180 may be thicker at a portion adjacent to the polysilicon pattern 172 than at a portion adjacent to a dielectric pattern. For example, at one sidewall of the polysilicon pattern 172, horizontal width of the polysilicon pattern 172 may be substantially equal to the thickness of the metal layer 180. In this case, the polysilicon patterns 172 may react to a metal material during a subsequent silicidation process. Since the data storage pattern 152 is locally formed in the recessed region 142, the metal layer 180 may be conformally formed on a surface of the recessed region 144 of the substrate 100.

Referring to FIG. 9, a silicidation process may be performed to form a metal silicide by reacting the polysilicon patterns 172 and the impurity region 105 in the substrate 100. The silicidation process may include a heat treatment process in which a metal material reacts with silicon, and a process of removing a metal material that does not react to the silicon.

According to an embodiment, as the heat treatment process is performed, silicon in the polysilicon patterns 172 and in the impurity regions 105 reacts with the metal material of the metal layer 180. That is, while the silicon of the polysilicon pattern 172 is consumed, metal silicide layers 182 and 184 may be formed thereat. In other words, the silicon in the polysilicon patterns 172 may interact with metal in the metal layer 180, i.e., a layer directly contacting the polysilicon patterns 172, so the polysilicon patterns 172 may be transformed into the gate silicide layers 182 in the recessed regions 142. Similarly, the silicon of the impurity regions 105 may interact with metal in the metal layer 180, i.e., a layer directly contacting the impurity regions 105, so the impurity regions 105 may be transformed into the common silicide layers 184. That is, the gate silicide layers 182 between the dielectric patterns 111˜118 and the common silicide layers 184 on the impurity region 105 may be formed by a silicidation process. Each of the gate and common source silicide layers 182 and 184 may be, e.g., of a cobalt silicide layer, a titanium silicide layer, a nickel silicide layer, and/or a tungsten silicide layer.

According to an embodiment, the heat treatment process may be performed at a temperature ranging from about 250° C. to 800° C. A rapid terminal process (RTP) apparatus or a furnace may be used during the heat treatment process. Thickness and phase of the gate and common silicide layers 182 and 184 may vary with recipes (time and temperatures) of the heat treatment process.

For example, the heat treatment process may allow the metal layer 180 interact with only a part of the polysilicon pattern 172, as shown in FIG. 12, so a partial polysilicon pattern 174 may remain in the recessed region 142. That is, the gate electrode WL may include the partial polysilicon pattern 174 adjacent to the semiconductor pattern 132 and the gate silicide layer 182 adjacent to the trench 140.

According to an embodiment, all of the polysilicon patterns 172 may be formed into the gate silicide layers 182, such that a high-resistivity polysilicon pattern may not remain. That is, a silicidation process according to an embodiment may be a full silicidation process, in which all of the polysilicon patterns 172 stacked on the substrate 100 react with the metal layer 180. As the full silicidation process is performed, gate silicide layers 182 may be formed at the positions of the polysilicon patterns 172. As described with reference to FIGS. 8 and 18, the thickness of the metal layer 180 may be adjusted, such that all of the polysilicon patterns 172 is transformed into the metal silicide layer 182, i.e., to provide sufficient metal material to transform all the polysilicon patterns 172 into metal silicide. For example, the deposition thickness of the metal layer 180 on one sidewall of a polysilicon pattern 172 may be substantially equal to the horizontal width, i.e., along the x-axis, of the polysilicon pattern 172. After the full silicidation process is performed, vertical thickness (length in a direction of the z-axis) of the common source silicide layer 184 formed at the impurity region 105 may substantially equal the horizontal width of the gate silicide layer 182.

For example, the metal layer 180 may be formed of titanium (Ti), so the gate silicide layer 182 may be formed of a titanium silicide. It is noted, however, that as titanium silicide requires a high temperature of above about 700° C. during the silicidation process, i.e., may have reduced thermal stability during a manufacturing process of a semiconductor device, and as the titanium silicide layer has low resistance only in a specific phase, i.e., there may be a difficulty during formation of the titanium silicide layer, nickel silicide having resistivity and formation temperature lower than that of the titanium silicide may provide further improvements in the manufacturing of the three-dimensional semiconductor memory device.

Similarly, the metal layer 180 may be formed of cobalt (Co), so the gate silicide layer 182 may be formed of a cobalt silicide. It is noted, however, that as cobalt silicide may be short-circuited by agglomeration during a high-temperature rapid thermal process (RTP) as linewidth and deposition thickness become smaller, i.e., a void may be formed between a polysilicon pattern and the silicide layer 182 by diffusion of silicon during a silicidation process, nickel silicide having resistivity and formation temperature lower than that of the cobalt silicide may provide further improvements in the manufacturing of the three-dimensional semiconductor memory device.

For example, according to example embodiments, each of the gate and common silicide layers 182 and 184 may be formed of a nickel silicide layer, which may include at least one of NiSi, NiSi₂, Ni₃Si₂, Ni₂Si, and Ni₃₁Si₁₂. Further, among the nickel silicide layers, a nickel monosilicide layer, e.g., NiSi, may be formed at a lower temperature than other nickel silicide layers, e.g., Ni₃Si₂, Ni₂Si, and Ni₃₁ Si₁₂, and may have low resistivity of about 14˜20 micro-ohm centimeters. Thus, the gate and common silicide layers 182 and 184 may be formed of nickel monosilicide layers having substantially equal contents of silicon and nickel. Such a nickel monosilicide layer may be formed by performing a heat treatment process at a temperature ranging from about 250° C. to about 500° C. That is, since each of the gate and common silicide layers 182 and 184 is formed of nickel monosilicide having lower resistance than metal such as tungsten to a thickness less than about 500 angstroms, resistances of the gate electrodes WL and the common source line CSL may be reduced.

After the heat treatment process is performed, a wet etch process may be performed to remove a non-reactive metal layer, i.e., remaining portions of metal not reacted with the silicon. For example, the non-reactive metal layer may be removed using a mixture of H₂SO₄ and H₂O₂ as an etch solution.

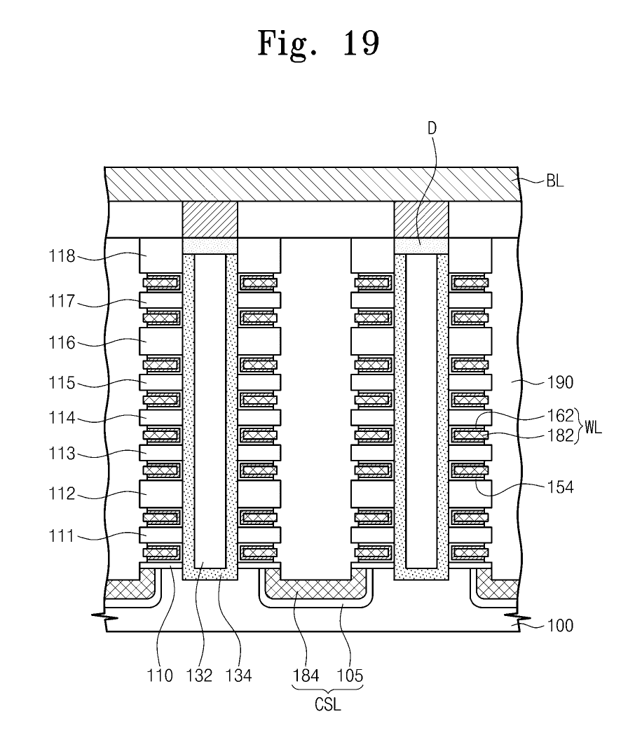

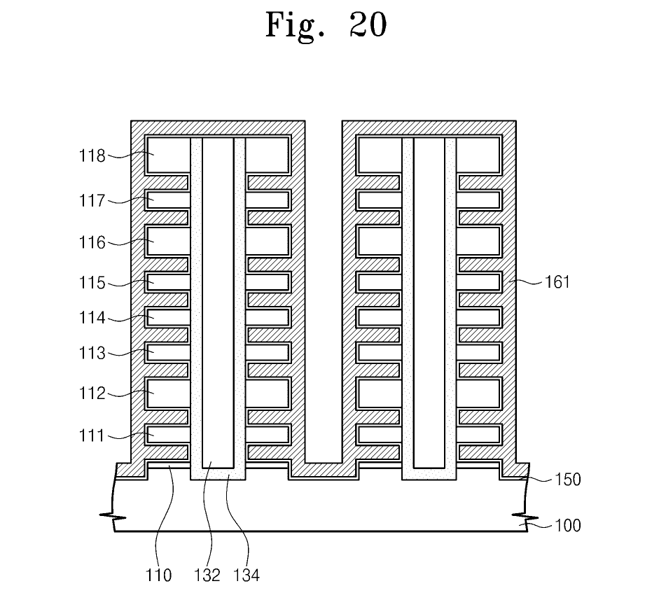

Following removal of the non-reactive metal layer, the gate silicide layers 182 and the common silicide layers 184 may be exposed to a trench. According to one embodiment, as shown in FIGS. 11 and 14, the silicidation process may allow one-side walls of the gate silicide layers 182 to protrude more than, i.e., extend beyond, one sidewall of the dielectric patterns 111˜118. Moreover, as shown in FIG. 19, the silicidation process may allow the common silicide layer 184 to overlap a lower portion of the gate silicide layer 182.

Referring to FIG. 10, a gate separation dielectric pattern 190 may be formed in the trenches 140. Forming the gate separation dielectric pattern 190 may include filling the trenches 140, i.e., where the non-reactive metal layer is removed, with at least one insulating material. According to an embodiment, the gate separation dielectric pattern 190 may include at least one of, e.g., silicon oxide, silicon nitride, and silicon oxynitride. According to another embodiment, before forming the gate separation dielectric pattern 190 in the trenches 140, a capping layer may be formed to prevent oxidation of the gate and common silicide layers 182 and 184. The capping layer may be formed of nitride, e.g., silicon nitride.

After forming the gate separation dielectric pattern 190, a drain region D may be formed at an upper portion of the semiconductor pattern 132 by implanting impurities having a conductivity type opposite to that of the semiconductor pattern 132. Alternatively, the drain region D may be formed at the upper portion of the semiconductor pattern 132 before forming the trenches 140 described in FIG. 4.

Bitlines BL may be formed over the gate electrodes WL to electrically connect the semiconductor patterns 132. The bitlines BL may be formed in a direction crossing the gate electrodes WL formed in the shape of lines. The bitlines BL may be connected to the drain region D on the semiconductor patterns 132 by a contact plug.

According to the method for manufacturing a three-dimensional semiconductor memory device described with reference to FIGS. 1 to 10, the data storage layer 150, the barrier metal pattern 162, and the gate electrode WL may be sequentially formed in the recessed region 142 of the thin film structure ST, i.e., thin film stacked structures ST. The data storage layer 150 and the barrier metal layer 162 may cover a top surface and a bottom surface of the gate electrode WL.

Meanwhile, in a manufacturing method according to another embodiment, a barrier metal layer may be removed at top and bottom surfaces of the dielectric patterns 111˜118. That is, the barrier metal pattern may be locally formed on a data storage layer adjacent to a sidewall of the semiconductor pattern 132.

Hereinafter, a method for manufacturing a three-dimensional semiconductor memory device according to another embodiment of the inventive concept will now be described below with reference to FIGS. 20 to 24. In the manufacturing method according to another embodiment, forming the thin film structure ST with the recessed regions 142 is substantially identical to that described with reference to FIGS. 2 to 5. Therefore, the manufacturing method according to another embodiment of the inventive concept will be described in succession of FIG. 5.

Referring to FIG. 20, the data storage layer 150 may be conformally formed on the thin film structure ST, i.e., where recessed regions 142 are formed. As described with reference to FIG. 6, the data storage layer 150 may conformally cover a sidewall of the semiconductor pattern 132 exposed to the recessed region 142 and bottom and top surfaces of the dielectric patterns 111˜118 defining the recess region 142. The data storage layer 150 may also be conformally formed on sidewalls of the dielectric patterns 111˜118 exposed to the trench 140 and a surface of the substrate 100.

According to an embodiment, the data storage layer 150 may be a charge storage layer. For example, the charge storage layer may be one of a charge trapping dielectric layer, a floating gate electrode, and an insulating layer including conductive nanodots. In the case where the data storage layer 150 is a charge storage layer, data stored in the data storage layer 150 may vary using Fowler-Nordheim tunneling (FN tunneling) caused by a voltage difference between a vertical semiconductor layer pattern and gate conductive patterns. The data storage layer 150 may be a thin film (e.g., a thin film for a phase change memory or a thin film for a variable resistance memory) which is capable of storing data based on a different operation principle.

As described with reference to FIG. 6 and FIGS. 11 to 16, the data storage layer 150 may be provided in various shapes.

A barrier metal layer 161 may be formed in the recessed region where the data storage layer 150 is formed. As described with reference to FIG. 6, the barrier metal layer 161 may prevent a metal material from penetrating the data storage layer 150 and is formed of a conductive material having low resistivity to reduce resistance of a gate electrode. The barrier metal layer 161 may be formed of a metal, e.g., at least one of titanium, tantalum, and tungsten, and/or a conductive metal nitride, e.g., at least one of titanium nitride, tantalum nitride, and tungsten nitride.

In this embodiment, the barrier metal layer 161 may be formed to a thickness that is equal to or greater than half the vertical thickness of the recessed region 142. Thus, the barrier metal layer 161 may be conformally formed in the trench 140 while filling the recessed region 142. That is, the barrier metal layer 161 may fill a part of the trench 140 and define an empty region at a center of the trench 140. In this case, the empty region may have an open top. The barrier metal layer 161 may be formed using a deposition technique (e.g., a CVD, ALD or sputtering technique) which is capable of providing superior step coverage.

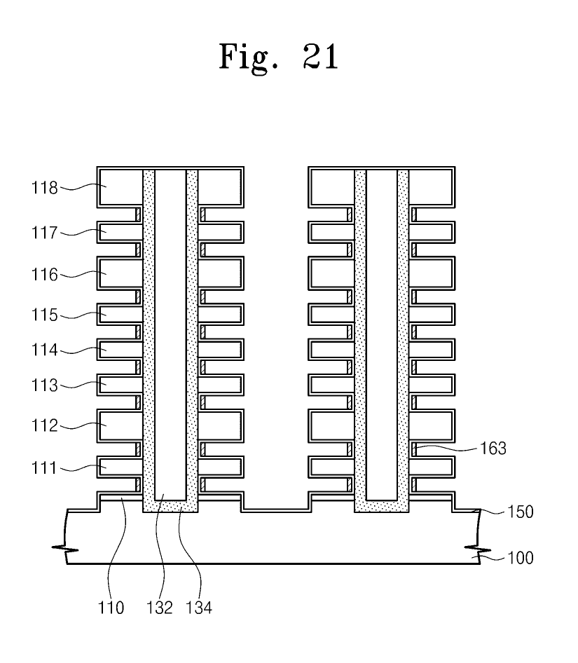

Referring to FIG. 21, a portion of the barrier metal layer 161 may be etched to form a barrier metal pattern 163 at the respective recessed regions 142. For example, the barrier metal pattern 163 may be formed by uniformly etching the barrier metal layer 161 vertically and horizontally. At this point, the data storage layer 150 may be used as an etch-stop layer.

According to an embodiment, the barrier metal layer 161 may be etched by performing an isotropic etch process. The isotropic etch process may be performed until the barrier metal layer 161 is vertically separated and remains at a portion of the recessed region 142. That is, the barrier metal layer 161 may be vertically separated by an isotropic etch process and a barrier metal pattern 163 may be formed to fill the recessed region 142. As the isotropic etch process continues to be performed, horizontal width of the barrier metal pattern 163 may be reduced in the recessed region 142. As the horizontal width of the barrier metal pattern 163 is reduced, the data storage layer 150 formed on top and bottom surfaces of the dielectric patterns 111˜118 may be exposed. The horizontal width of the barrier metal pattern 163 remaining in the recessed region 142 may be about 10 to 100 angstroms.

The isotropic etch process for the barrier metal layer 161 may be a wet etch process using an etch solution or a dry etch process using an etch gas. For example, etching the barrier metal layer 161 may be carried out by chemical mechanical etch such as RIE, wet etching using an etchant, chemical pyrolysis etching (e.g., gas-phase etch (GPE)), or a combination thereof.

For example, when the barrier metal layer 161 is formed of titanium nitride, it may be etched using a gas-phase etchant generated from a source gas containing a fluorine group (e.g., CF₄ and C₂F₆) and a chlorine group (e.g., Cl₂). The use of gas-phase etchant allows the barrier metal layer 161 exposed to the trench 140 to be uniformly etched vertically and horizontally.

When the barrier metal layer 161 formed of titanium nitride is removed, a mixture of ammonium hydroxide (NH₄OH), hydrogen peroxide (H₂O₂), and deionized water (DI water) and a mixture of sulfuric acid (H₂SO₄) and hydrogen peroxide (H₂O₂) may be used. The mixture of ammonium hydroxide (NH₄OH), hydrogen peroxide (H₂O₂), and deionized water (DI water) is generally referred to as standard clean 1 (SC1).

Decrease of vertical thickness of the recessed region 142 may be reduced by removing the conductive barrier metal layer 161 formed on the top and bottom surfaces of the dielectric patterns 111˜118. In addition, since the conductive barrier metal layer 161 has higher resistance than a silicide layer, resistance of a gate electrode may be further reduced by removing the conductive barrier metal layer 161 formed on the top and bottom surfaces of the dielectric patterns 111˜118.

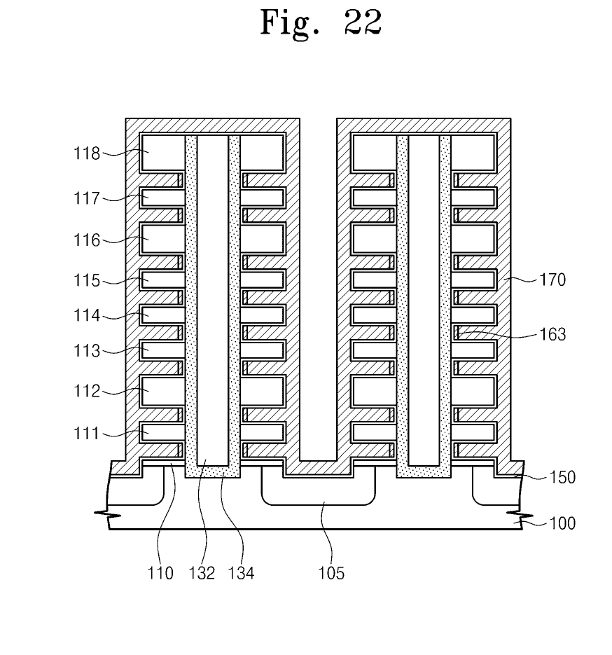

Referring to FIG. 22, after locally forming the barrier metal pattern 163 in the recessed regions 142, the polysilicon layer 170 may be formed at the recessed regions 142 where the barrier metal layer 161 is formed. As described with reference to FIG. 6, the polysilicon layer 170 may be formed of polysilicon doped with n-type or p-type impurity (boron or phosphorous) or amorphous polysilicon. The polysilicon layer 170 may be formed using a deposition technique (e.g., CVD or ALD) which is capable of providing superior step coverage. Thus, the polysilicon layer 170 may be conformally formed in the trench 140 while filling the recessed regions 142.

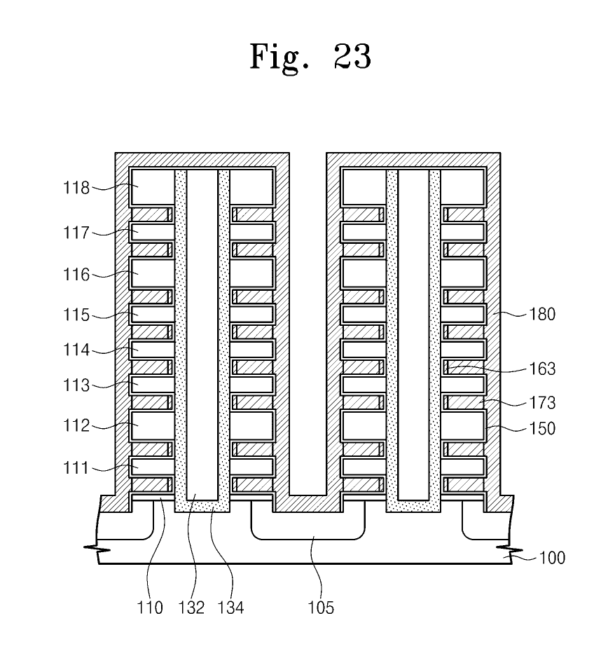

As described with reference to FIG. 7, the polysilicon layer 170 filling the trench 140 may be removed to form the polysilicon pattern 172 at the respective recessed regions 142. In another embodiment, portions of the polysilicon layer 170 may be removed to form a polysilicon pattern 173 at the respective recessed regions 142. Unlike the polysilicon patterns 172 that define a flat, i.e., level, sidewall with the data storage layer 150 (FIG. 7), the polysilicon patterns 173 have sidewalls that are level with sidewalls of the dielectric patterns 111˜118 (FIG. 23).

According to another embodiment, since the barrier metal pattern 163 is locally formed at a sidewall portion of the semiconductor pattern 132, the polysilicon layer 170 filling the recessed region 142 may come in direct contact with the data storage layer 150 deposited on upper and lower portions of the dielectric patterns 111˜118. For example, the barrier metal pattern 163 may be formed between the polysilicon pattern 173 and the data storage layer 150 and top and bottom surfaces of the polysilicon pattern 173 may come in direct contact with the data storage layer 150.

Referring to FIG. 23, after forming polysilicon patterns 173, the impurity region 105 may be formed in the substrate 100 below the trench 140. The impurity region 105 may be formed using an uppermost insulating layer of the thin film structure as an ion implantation mask. Thus, the impurity region 105 may have the shape of a line extending in one direction, like a horizontal shape of the trench 140.

In addition, after forming the polysilicon patterns 173, a portion of the data storage layer 150 below the trench 140 may be etched to expose a surface of the substrate 100. At this point, the data storage layer 150 formed over the uppermost dielectric pattern and on sidewalls of the dielectric patterns 111˜118 may be also etched.

As described with reference to FIG. 8, the metal layer 180 is formed to cover the impurity region 105 and the polysilicon patterns 173 exposed to the trench 140. The metal layer 180 may be formed of a refractory metal material, e.g., at least one of cobalt (Co), titanium (Ti), nickel (Ni), tungsten (W), and/or molybdenum (Mo).

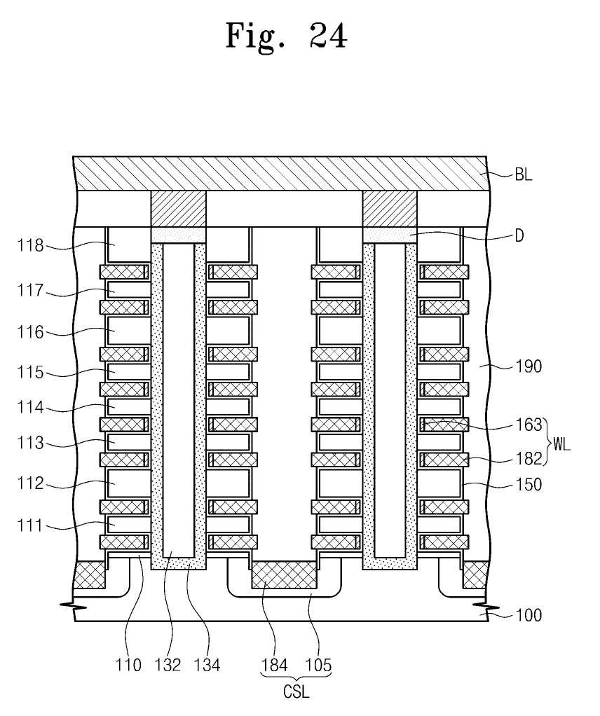

A silicidation process may be performed to form a metal silicide by reacting the metal layer 180 with the impurity region 105 in the substrate 100. The silicidation process may be performed the same way described with reference to FIG. 9. Accordingly, as shown in FIG. 24, a part or all of the polysilicon patterns 173 may react with the metal layer 180 to form the gate silicide layer 182. Additionally, the common silicide layer 184 may be formed on the impurity region 105. One sidewall of the gate silicide layer 182 may be in contact with the barrier metal pattern 163, and a top surface and a bottom surface of the gate silicide layer 182 may be in contact with the data storage layer 150.

According to another embodiment, resistance may be further reduced than at the gate electrode WL in a semiconductor memory device manufactured according to an embodiment of the inventive concept by removing the barrier metal pattern 163 having higher resistance than metal silicide at the bottom and top surfaces of the dielectric patterns 111˜118.

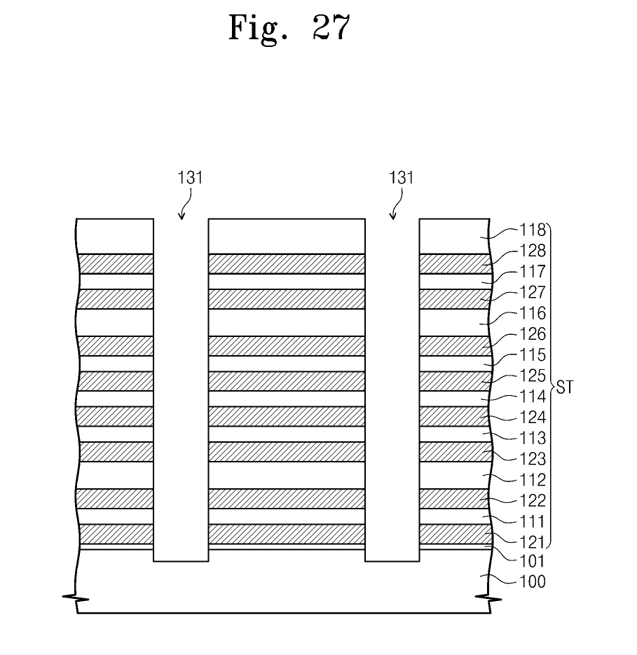

Hereinafter, a method for manufacturing a three-dimensional semiconductor memory device according to yet another embodiment of the inventive concept will now be described below with reference to FIGS. 27 to 32.

Referring to FIG. 27, the film structure ST is formed on the substrate 100. The thin film structure ST includes polysilicon layers 121˜128 and insulating layers 111˜118 which are alternately stacked. Each of the insulating layers 111˜118 may be formed of at least one of a thermal oxide, silicon oxide, silicon nitride, and silicon oxynitride. Each of the polysilicon layers 121˜128 may be formed of polysilicon doped with n-type or p-type impurity (boron or phosphorous) or amorphous polysilicon. The buffer insulating layer 101, which is in contact with a surface of the substrate 100, may be used as a portion of a gate insulating layer of a lowermost gate electrode and have an extremely small thickness. A lowermost insulating layer may be formed of oxide, e.g., thermal oxide.

In the thin film structure ST, thicknesses of the polysilicon layers 121˜128 determine channel length of a memory cell transistor. According to one embodiment, since the polysilicon layers 121˜128 are formed by a deposition process, channel length may be adjusted more precisely than when they are formed using a patterning technique.

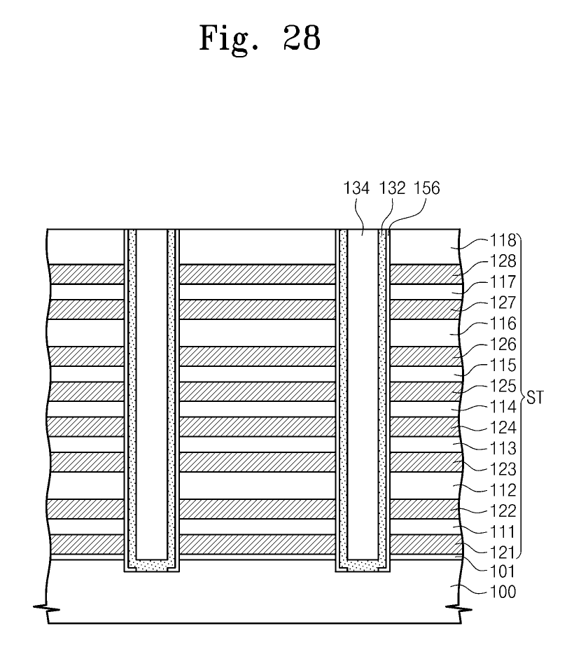

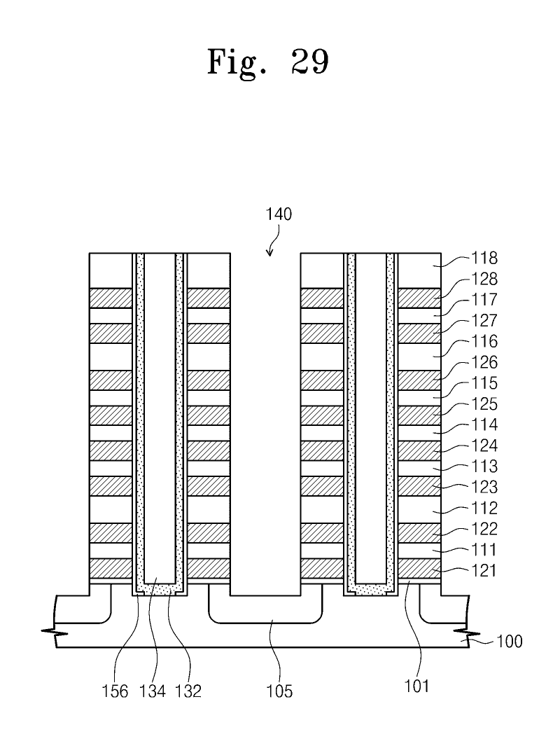

A distance between the polysilicon layers 121˜128 (i.e., thickness of the insulating layers 111˜128) may have a smaller range than a maximum vertical length of an inversion region generated at a semiconductor pattern 132 formed in a subsequent process. According to an embodiment, thicknesses of the polysilicon layers 121˜128 may be equal to each other. Alternatively, thicknesses of uppermost and lowermost polysilicon layers 121 and 128 may be greater than those of the other polysilicon layers 122˜127. As shown in FIG. 28, thickness of an insulating layer of a predetermined layer may be greater than that of each of the other insulating layers 111˜118. The number of thin films constituting the thin film structure ST, thickness of each of the thin films, and material of each of the thin films may be variously provided considering electrical characteristics of a memory cell transistor and technical difficulties in patterning the thin films.

Next, the thin film structure ST is patterned, such that openings 131 are formed to expose the substrate 100. Specifically, as described with reference to FIG. 2, forming the openings 131 may include forming a mask pattern (not shown) to define plan positions of the openings 131 and anisotropically etching the thin film structure ST by using the mask pattern as an etch mask.

In these embodiments, the openings 131 may be formed to expose sidewalls of the polysilicon layers 121˜128 and the insulating layers 111˜118. In a horizontal shape, each of the openings 131 may be formed in the shape of a cylindrical hole or a rectangular-parallelepiped hole. An anisotropic etch process may allow the opening 131 to have width varying with a distance from the substrate 100. As described with reference to one embodiment, the openings 131 may be formed in the shape of a line or a rectangle. Moreover, the openings 131 may be formed to expose a top surface of the substrate 100. While the openings 131 are formed, the exposed top surface of the substrate 100 may be recessed to a predetermined thickness by overetching.

Referring to FIG. 28, a data storage layer 156 and the semiconductor pattern 132 may be formed in the openings 131.

The data storage layer 156 may be formed using a deposition technique (e.g., CVD, ALD or sputtering) which is capable of providing superior step coverage and may be formed to a thickness less than half the width of the opening 131. Accordingly, the data storage layer 156 may substantially conformally cover one-side walls of the polysilicon layers 121˜128 and the insulating layers 111˜118 exposed to the opening 131. Since the data storage layer 156 is formed using a deposition technique, it may be conformally deposited on a top surface of a vertical semiconductor layer exposed by the opening 131.

As described in one embodiment, the data storage layer 156 may include a charge storage layer. For example, the charge storage layer may include either one of a charge trapping dielectric layer and an insulating layer including a floating gate electrode or conductive nanodots. In addition, as described in an embodiment, the data storage layer 156 may include a blocking dielectric layer, a charge trapping layer, and a tunneling dielectric layer which are sequentially stacked in the order named.

The semiconductor pattern 132 formed in the openings 131 must be electrically connected to the substrate 100. Hence, before forming the semiconductor pattern 132 in the opening 131, the data storage layer 156 is patterned to expose a portion of a top surface of the substrate 100, i.e., so a portion of a horizontal semiconductor layer may contact the substrate 100 through the patterned data storage layer 156. For patterning the data storage layer 156, temporary spacers (not shown) may be formed within the opening 131 to cover inner sidewall of the data storage layer 156. The temporary spacers may mitigate an etch damage to the data storage layer 156 in a patterning process for etching the data storage layer 156. According to an embodiment, the temporary spacers may be of a materials capable of minimizing an etch damage to the data storage layer 156. For example, in the case where the data storage layer 156 contacting temporary spacers is a silicon oxide layer, the temporary spacers may be formed of silicon nitride. According to a modified embodiment, the spacers may be formed of the same material as the semiconductor pattern 132. For example, the temporary spacers may be formed of amorphous silicon or polysilicon. In this case, the spacer may be used as the semiconductor pattern 132 without a special removal process. Thereafter, the data storage layer 156 is etched using the temporary spacers as etch masks. Thus, the top surface of the horizontal semiconductor layer may be exposed at the bottoms of the openings 131. After etching the data storage layer 156, the temporary spacers may be removed while minimizing the etch damage to the data storage layer 156.

The semiconductor pattern 132 is formed to cover the data storage layer 156 while being in contact with the substrate 100 at the bottom of the opening 131. The semiconductor pattern 132 may be formed using a deposition process capable of providing superior step coverage. The semiconductor pattern 132 may be deposited to a thickness that is equal to or less than half the width of the opening 131. In this case, the semiconductor pattern 132 may fill a portion of the opening 131 and define an empty region at the center portion of the opening 131. That is, the semiconductor pattern 132 may be formed in the shape of a hollow cylinder or a shell. Thickness of the semiconductor pattern 132 (i.e., thickness of the shell) may be less than a width of a depletion region to be formed thereat or less than an average length of silicon grains constituting polysilicon. The empty region defined by the semiconductor pattern 132 may be filled with the buried dielectric pattern 134. According to another embodiment, the semiconductor pattern 132 may fill up the opening 131 by a deposition process. In this case, the semiconductor pattern 132 may be planarized after depositing a semiconductor layer in the opening 131.

According to another embodiment, the semiconductor pattern 132 may be formed of single-crystalline silicon by depositing amorphous silicon or polysilicon and changing the phase of the amorphous silicon or the polysilicon through a heat treatment process, e.g., an annealing process. According to another embodiment, the semiconductor pattern 132 may be a single-crystalline semiconductor formed through an epitaxial growth process using the substrate 100 as a seed.

Referring to FIG. 29, trenches 140 are formed between adjacent semiconductor patterns 132 to expose the substrate 100, which is similar to the description with reference to FIG. 4. The trench 140 may be spaced apart from the semiconductor patterns 132 to expose sidewalls of the polysilicon layers 121˜128 and the insulating layers 111˜118. In a horizontal shape, the trenches 140 may be formed in the shape of parallel lines or a rectangle. In terms of vertical depth, the trench 140 may be formed to expose the buffer insulating layer 101 on the substrate 100. Alternatively, the trenches 140 may be formed to expose a top surface of the substrate 100. During the formation of the trenches 140, the exposed top surface of the substrate 100 may be recessed to a predetermined depth. Additionally, an isotropic etch process may allow a trench to have width varying with a distance from the substrate 100.

As the trenches 140 are formed, a line-type thin film structure ST may be formed in which polysilicon layers 121˜128 and insulating layers 111˜118 are alternately stacked. A plurality of semiconductor patterns 132 may penetrate the thin film structure ST formed in the shape of one line.

After forming the trenches 140, the impurity region 105 may be formed in the substrate 100. The impurity region 105 may be formed by an ion implantation process using the thin film structures ST on the substrate ST as etch masks. Thus, like the horizontal shape of the trench 140, the impurity region 105 may have the shape of line extending in one direction. Due to diffusion of impurities, the impurity region 105 may overlap a portion of a lower region of the thin film structure ST. The impurity region 105 may have a conductivity type opposite to that of the substrate 105.

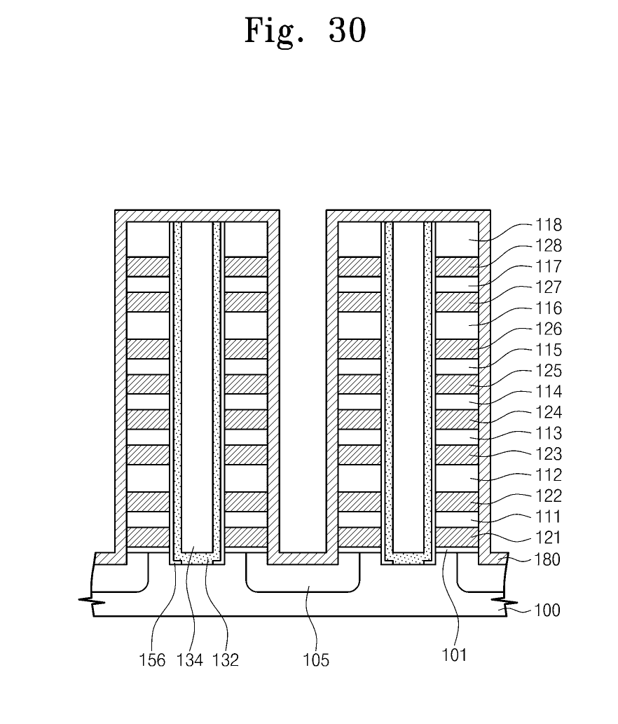

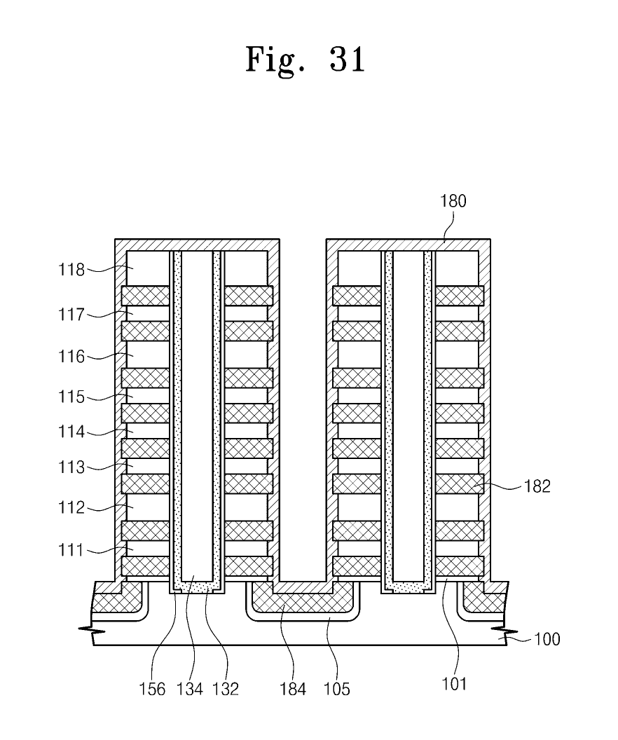

Referring to FIG. 30, the metal layer 180 is conformally formed on the substrate 100 where thin film structures ST are formed. That is, the metal layer 180 may cover sidewalls of the polysilicon patterns 121˜128 and the dielectric patterns 111˜118 exposed to the trench 140 and a top surface of an impurity region. As described with reference to FIG. 8, the metal layer 180 may be formed of a refractory metal, e.g., at least one of cobalt (Co), titanium (Ti), nickel (Ni), tungsten (W), and/or molybdenum (Mo), and or of an alloy including at least one of, platinum (Pt), rhenium (Re), boron (B), aluminum (Al), and germanium (Ge).

Thickness of the metal layer 180 may be determined considering the horizontal width of the polysilicon pattern, resistance of the gate electrode WL, and resistance of the common source line CSL. For example, the metal layer 180 may be deposited to the substantially same thickness as a horizontal width of the polysilicon pattern. According to another embodiment, as described with reference to FIG. 17, the horizontal width of the polysilicon pattern may be reduced by recessing the polysilicon patterns 121˜128 before forming the metal layer 180.

Thereafter, a silicidation process is performed to form a metal silicide by reacting the metal layer 180 with the polysilicon patterns 121˜128 and the impurity region in the substrate 100. The silicidation process may include a heat treatment process and a process of removing a non-reactive metal layer 180.

As described in an embodiment, the heat treatment process may be performed using a RTP apparatus or a furnace at a temperature ranging from about 250° C. to about 800° C. Thus, as shown in FIG. 31, gate silicide layers 182 between the insulating layers 111˜118 and common silicide layers 184 on the impurity region may be formed.

In the case where the substrate 100 exposed to the trench 140 is recessed when the heat treatment process is performed, silicon in a lower portion of a stacked structure may also react to the metal layer 180. In one embodiment, the silicidation process may be a full silicidation process in which all of the polysilicon patterns 172 stacked on the substrate 100 react with the metal layer 180. Accordingly, the gate silicide layer 182 may come in direct contact with the data storage layer 156. Additionally, in an embodiment, each of the silicide layers 182 and 184 may be a layer of nickel silicide, e.g., nickel monosilicide in which the contents of silicon and nickel are substantially equal to each other.

After forming the silicide layers 182 and 184 through the heat treatment process, the non-reactive metal layer 180 may be removed by performing a wet etch process. According to an embodiment, the silicidation process may allow one-side walls of the gate silicide layers 182 to be more protrusive, i.e., have a longer width along the x-axis, than one sidewall of the dielectric patterns 111˜118.

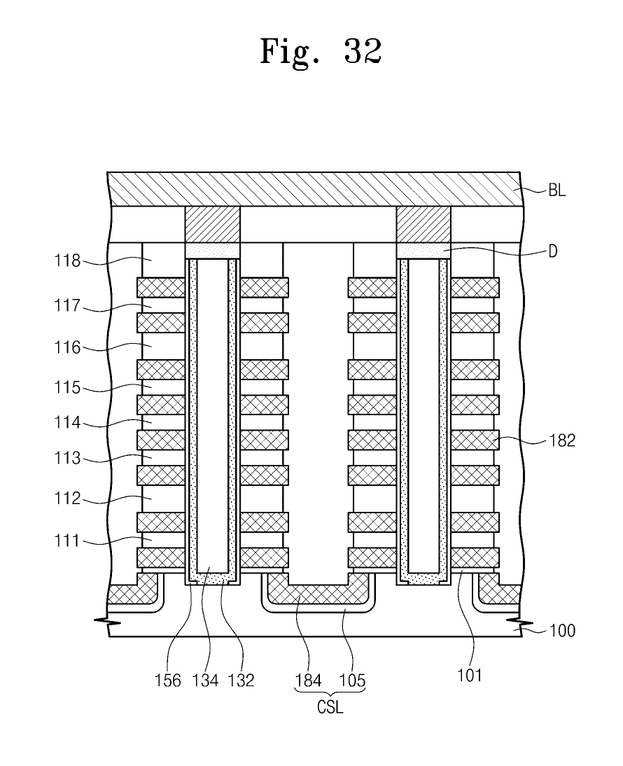

Referring to FIG. 32, the gate separation dielectric pattern 190 may be formed in the trench 140, and the drain region D may be formed at an upper portion of the semiconductor pattern 132. Bitlines BL may be formed over the semiconductor patterns 132 to cross the gate electrode WL and electrically connect the semiconductor patterns 132 to each other. The bitlines BL may be connected to the drain regions D by a contact plug.

As shown in FIG. 10, the three-dimensional semiconductor memory device manufactured according to the foregoing embodiments includes a gate structure having a plurality of gate electrodes vertically stacked on the substrate 100, semiconductor patterns connected to the substrate 100 across one sidewall of the gate structure, a data storage pattern between the semiconductor pattern 132 and the gate electrode WL, and a common source conductive line CSL disposed in the substrate 100 between the gate structures. The gate electrodes WL and the common source conductive line CSL include the same metal silicide layer.

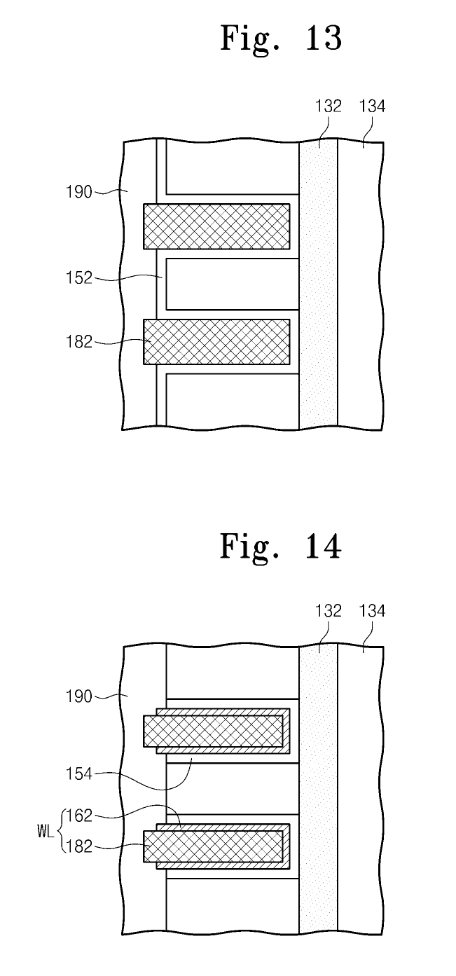

Specifically, the gate electrode WL may include the barrier metal pattern 162 and the gate silicide layer 182. The gate silicide layer 182 may be in direct contact with the barrier metal pattern 162. According to an embodiment, the barrier metal pattern 162 covers one sidewall and top and bottom surfaces of the gate silicide layer 182. According to another embodiment, as shown in FIG. 13, a barrier metal pattern may be omitted between the gate silicide layer 182 and the data storage patter 152. The gate silicide layer 182 may be formed of, e.g., nickel monosilicide, and the vertical thickness of the gate silicide layer 182 may be about 100 to 500 angstroms. The barrier metal pattern 162 may be formed of conductive metal nitride, e.g., titanium nitride, tantalum nitride, or tungsten nitride, and the thickness of the barrier metal pattern 162 may be about 10 to 100 angstroms.

The common source conductive line CSL may include the impurity region 105 in the substrate 100 between gate structures, and the common source silicide layer 184 on the impurity region 105. The common source silicide layer 184 may be formed of nickel monosilicide, e.g., of a same material as the gate silicide 182.

When such a three-dimensional semiconductor memory device operates, an inversion region may be generated the semiconductor pattern 132 adjacent to the gate electrodes WL. The inversion region may extend to a portion adjacent to the dielectric patterns 111˜118 between the gate electrodes WL due to a fringing field from the gate electrodes WL to which a predetermined voltage is applied. An inversion region adjacent to the dielectric patterns 111˜118 may be used as source/drain regions of transistors. In this case, the ground selection transistor GST, memory cell transistors MCT, and string selection transistor SST shown in FIG. 1 may be electrically connected by sharing inversion regions formed by a fringing field from the gate electrodes WL to which a predetermined voltage is applied. Thicknesses of the dielectric patterns 111˜118 between the gate electrodes WL may be adjusted such that inversion regions are shared by a fringing field. Horizontal width of the inversion region generated at the semiconductor pattern 132 may be equal to or less than thickness of the semiconductor pattern 132. When the horizontal width of the inversion region is equal to the thickness of the semiconductor pattern 132, the semiconductor pattern 132 may be fully depleted when the three-dimensional semiconductor memory device operates.

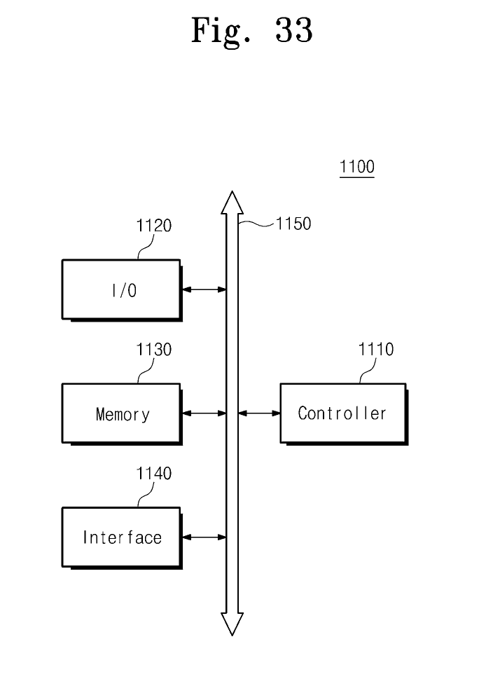

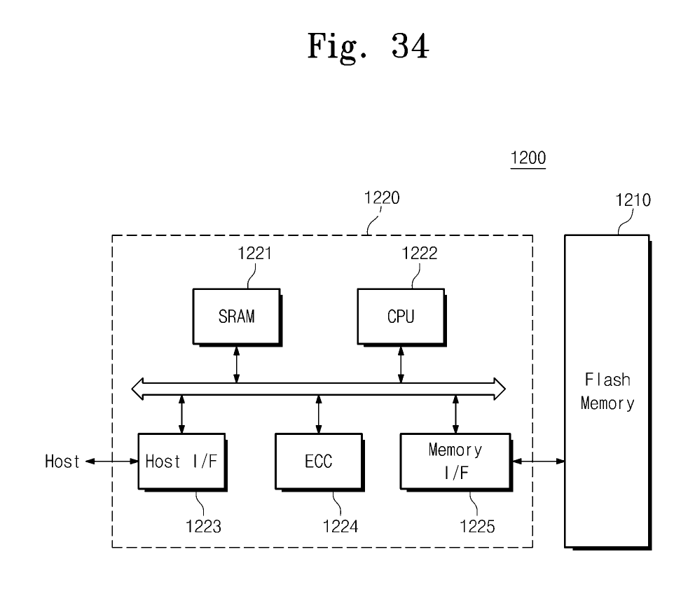

FIG. 33 is a block diagram of an example of a memory system 1100 including a semiconductor memory device manufactured according to exemplary embodiments of the inventive concept.

Referring to FIG. 33, the memory system 1100 may be applied to, e.g., personal digital assistants (PDAs), portable computers, web tablets, wireless phones, mobile phones, digital music players, memory cards, or any other device capable of transmitting and/or receiving information in wireless environments.

The memory system 1100 includes a controller 1110, an input/output (I/O) device 1120, e.g., a keypad, a keyboard and a display, a memory 1130, an interface 1140, and a bus 1150. The memory 1130 and the interface 1140 communicate with each other through the bus 1150.

The controller 1110 includes at least one microprocessor, at least one digital signal processor, at least one micro controller or other process devices similar to the microprocessor, the digital signal processor, and the micro controller. The memory 1130 may be used to store an instruction executed by the controller 1110. The input/output device 1120 may receive data or a signal from the outside of the system 1100 or transmit data or a signal to the outside of the system 1100. For example, the input/output device 1120 may include a keyboard, a keypad, and/or a display.

The memory 1130 includes a nonvolatile memory device according to embodiments of the inventive concept. The memory 1130 may further include another type of memory, a random-accessible volatile memory device, and various types of memories.

The interface 1140 transmits data to a communication network or receives data from the communication network.

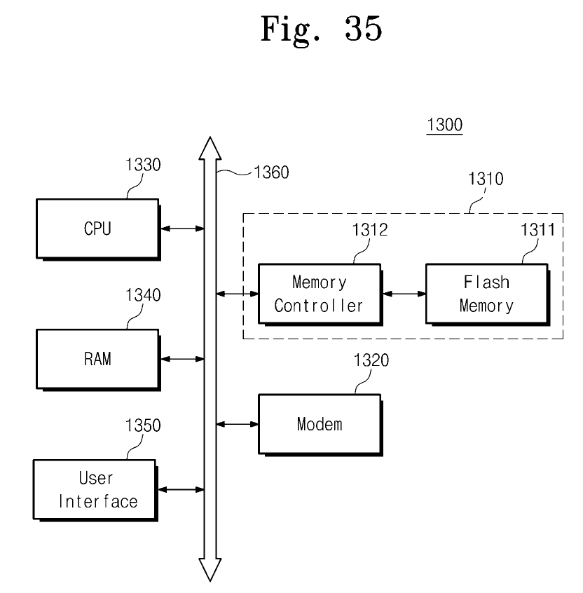

FIG. 34 is a block diagram of an embodiment of a memory card 1200 including a semiconductor memory device manufactured by exemplary embodiments of the inventive concept.

Referring to FIG. 34, the memory card 1200 for supporting a high-capacity data storage capability is fitted with a flash memory device 1210 according to the inventive concept. The memory card 1200 according to the inventive concept includes a memory controller 1220 controlling all the data exchanges between a host and the flash memory device 1210.

An SRAM 1221 is used as a work memory of a central processing unit (CPU) 1222. A host interface (I/F) 1223 includes a data exchange protocol of a host connected to the memory card 1200. An error correction block (ECC) 1224 detects and corrects errors included in data read from a multi-bit flash memory device 1210. A memory interface (I/F) 1225 interfaces with the flash memory device 1210 of the inventive concept. The CPU 1222 performs an overall control operation for data exchange of the memory controller 1220. Although not illustrated in the drawing, it is apparent to those skilled in the art that the memory card 1200 according to the inventive concept may be further provided with a ROM (not shown) storing code data for interfacing with the host.

FIG. 35 is a schematic block diagram of an embodiment of an information processing system 1300 fitted with a three-dimensional semiconductor memory device manufactured by embodiments of the inventive concept.

Referring to FIG. 35, a flash memory system 1310 is mounted in the information processing system 1300, e.g., a mobile device or a desktop computer. The information processing system 1300 includes the flash memory system 1310 and a modem 1320, a central processing unit (CPU) 1330, a random access memory (RAM) 1340, and a user interface 1350 which are each electrically connected to a system bus 1360. The flash memory system 1310 may be organized with the substantially same structure as a memory system or a flash memory system discussed above. The flash memory system 1310 stores data processed by the CPU 1330 or data received from an external device. The flash memory system 1310 may include a solid-state disk (SSD). In this case, the information processing system 1310 may stably store a large amount of data in a flash memory system 1311. The flash memory system 1310 may further include a memory controller 1312 connected to the flash memory 1311 and the bus 1360. With the increase of reliability, the flash memory system 1310 may reduce resources consumed to correct errors. Therefore, the flash memory device 1310 may provide a fast data exchange function to the information processing system 1300. Although not illustrated in the drawing, it is apparent to those skilled in the art that the information processing unit 1300 according to the inventive concept may be further provided with an application chipset, a camera image processor (CIS) and/or an input/output device.

A flash memory device or a memory system according to the inventive concept can be mounted with various types of packages. For example, the flash memory device or the memory system can be mounted by various types of packages such as PoP (package on package), ball grid array (BGA), chip scale package (CSP), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline (SOIC), shrink small outline package (SSOP), thin small outline (TSOP), thin quad flatpack (TQFP), system in package (SIP), multi chip package (MCP), wafer-level fabricated package (WFP), wafer-level processed stack package (WSP) and mounted.

As described above, the common source conductive line and gate electrodes include the same metal silicide layer. The metal silicide layer in the common source conductive line is formed simultaneously with the gate silicide layer of the gate electrode. Since resistances of the common source line and the gate electrodes decrease, operating speed of the three-dimensional semiconductor memory device can be enhanced. In addition, the gate electrode and common source conductive line are formed of metal silicide, e.g., nickel silicide having lower resistivity than a metal material, below a predetermined thickness. Therefore, integration density and characteristics of the three-dimensional semiconductor memory device may be improved.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1-12. (canceled)

13. A three-dimensional semiconductor memory device, comprising:
a plurality of gate structures disposed on a substrate, the plurality of gate structures being spaced apart from each other and including a plurality of gate electrodes having metal silicide layers;
semiconductor patterns traversing sidewalls of the gate structures and being connected to the substrate; and
a conductive line disposed in the substrate between the gate structures, the conductive line including a metal silicide layer.

14. The three-dimensional semiconductor memory device as claimed in claim 13, wherein the metal silicide layers in the gate electrodes and in the conductive line include nickel monosilicide having equal contents of silicon and nickel.

15. The three-dimensional semiconductor memory device as claimed in claim 14, wherein each gate electrode is the metal silicide layer.

16. The three-dimensional semiconductor memory device as claimed in claim 13, wherein the conducive line includes the metal silicide layer and an impurity region overlapping a portion of a lower region of the gate structure.

17. The three-dimensional semiconductor memory device as claimed in claim 13, wherein the gate structures extend in one direction, a horizontal width of the metal silicide layer of the gate electrode being equal to a vertical thickness of the metal silicide layer of the conductive line in a plane which is vertical to an extension direction of the gate structures.

18. The three-dimensional semiconductor memory device as claimed in claim 13, further comprising a barrier metal pattern locally formed between the semiconductor pattern and the gate electrode.

19. The three-dimensional semiconductor memory device as claimed in claim 18, wherein the barrier metal pattern is in direct contact with the metal silicide layer of the gate electrode.

20. The three-dimensional semiconductor memory device as claimed in claim 13, further comprising a data storage layer between the gate electrode and the semiconductor pattern.

21. The three-dimensional semiconductor memory device as claimed in claim 20, wherein the data storage layer extends from one sidewall of the gate electrode to top and bottom surfaces of the gate electrode.
